(19) United States
(12) Patent Application Publication
(10) Pub. No.: US 2008/0283910 A1
(43) Pub. Date: Nov. 20, 2008

(54) INTEGRATED CIRCUIT AND METHOD OF FORMING AN INTEGRATED CIRCUIT

(75) Inventors: Lars Dreeskornfeld, Dresden (DE); Dongping Wu, Dresden (DE); Jessica Hartwich, Dresden (DE); Juergen Holz, Dresden (DE); Arnd Scholz, Dresden (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: QIMONDA AG, Muenchen (DE)

(21) Appl. No.: 11/748,864

(22) Filed: May 15, 2007

(51) Int. Cl. H01L 29/78; H01L 21/336

(52) U.S. Cl. 257/332; 257/334; 438/270; 257/E29.262; 257/E21.409

(57) ABSTRACT

An integrated circuit and method of forming an integrated circuit is disclosed. One embodiment includes a FinFET of a first type having a first gate electrode and a FinFET of a second type having a second gate electrode. The first gate electrode is formed in a gate groove that is defined in a semiconductor substrate and a bottom side of a portion of the second gate electrode is disposed above a main surface of the semiconductor substrate.

### BACKGROUND

The present specification relates to an integrated circuit as well as to a method of manufacturing an integrated circuit. The specification also refers to a memory device as well as to a method of manufacturing such a memory device.

Generally, in the field of semiconductor technologies, many kinds of transistors having different characteristics such as threshold voltage (V_{TH}), speed and power consumption are known. Depending on the field of application, a transistor type having a high or low threshold voltage is desired. There are several concepts for increasing the channel lengths of the transistor. Further, attempts are made in order to fully deplete a transistor or to increase the channel width of a transistor. Accordingly, an appropriate transistor type can be selected depending on the desired application.

For example, it is often desired to combine two or more transistors having different characteristics on one single chip. In this case, a method might be useful by which transistors having different characteristics and a different structure may be manufactured in the same semiconductor substrate.

For these and other reasons, there is a need for the present invention.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIGS. 1A and 1B illustrate cross-sectional views of a transistor of a second type, respectively.

FIG. 2 illustrates a cross-sectional view of a transistor of a third type.

FIGS. 3A to 3C illustrate cross-sectional views of a transistor of a first type.

FIGS. 4A to 4C illustrate cross-sectional views of a modified transistor of the first type.

FIGS. 5A and 5B illustrate further modifications of the transistor of the first type, respectively.

FIGS. 5C to 5E illustrate further modifications of the transistors of the first, second and third types, respectively.

FIGS. 6A and 6B illustrate plan views of an integrated circuit, respectively.

FIGS. 6C to 6F illustrate methods of defining active areas.

FIGS. 6G and 6H illustrate embodiments of the method of manufacturing an integrated circuit.

FIGS. 7 to 18 illustrate cross-sectional views of a substrate after performing processes according to one embodiment.

FIGS. 19 to 20 illustrate further cross-sectional views of the substrate after performing processes according to one embodiment.

FIGS. 21 to 24 illustrate further views of a substrate after performing processes of still a further embodiment.

FIG. 25 illustrates a further embodiment of the method of forming a transistor.

FIGS. 26 to 34 illustrate cross-sectional views of a substrate when performing a method of manufacturing a transistor.

FIG. 35 illustrates an exemplary equivalent circuit diagram of a memory device having transistors of the several types.

FIG. 36A illustrates an electronic device having an integrated circuit.

FIG. 36B illustrates a data processing system having an integrated circuit.

FIG. 37 illustrates a further embodiment of the method of forming an integrated circuit.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

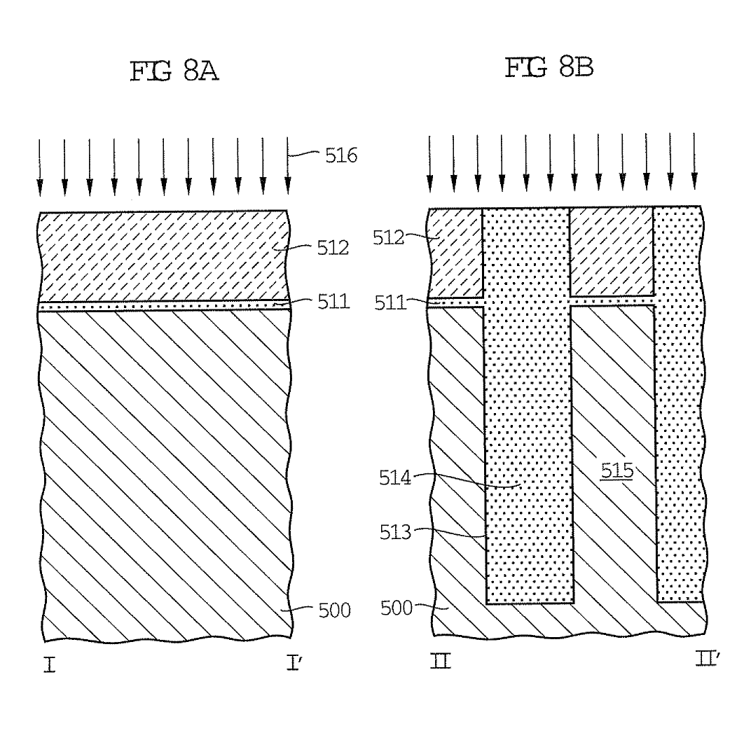

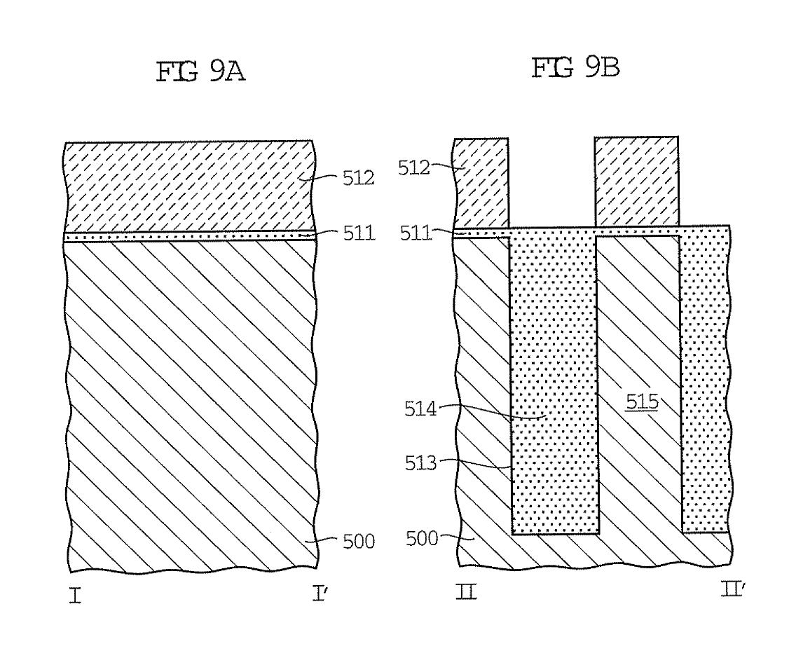

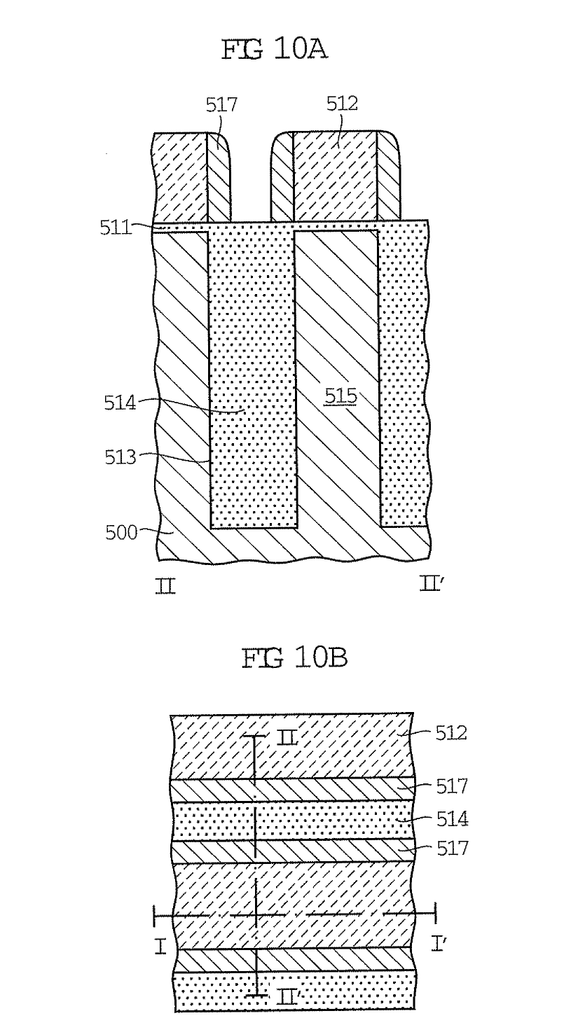

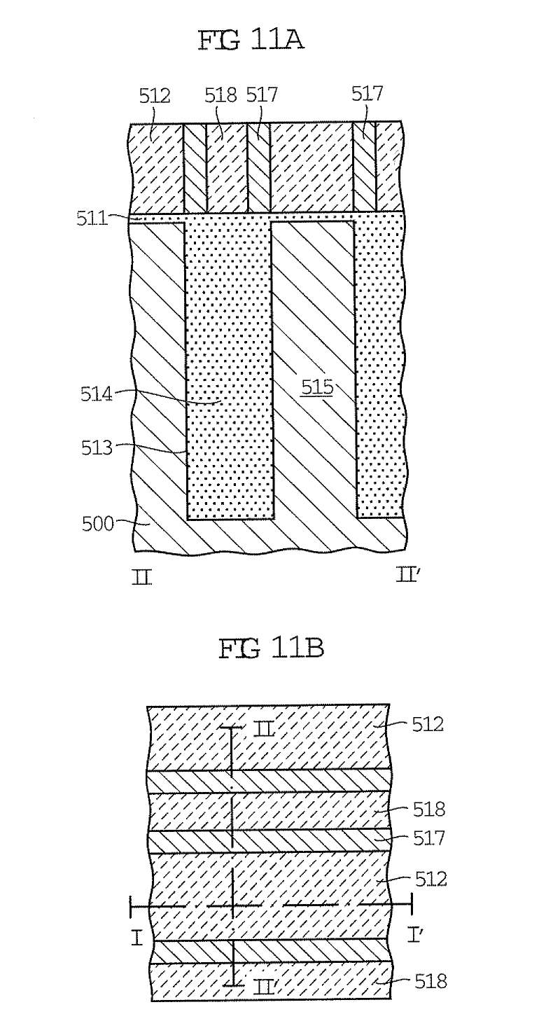

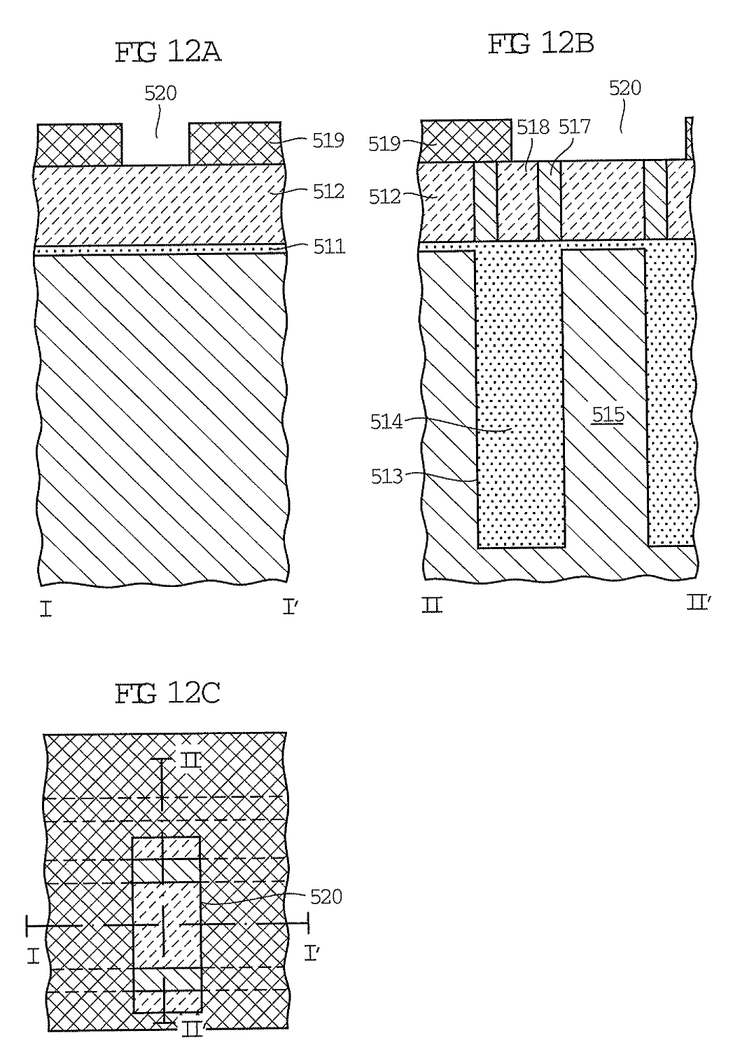

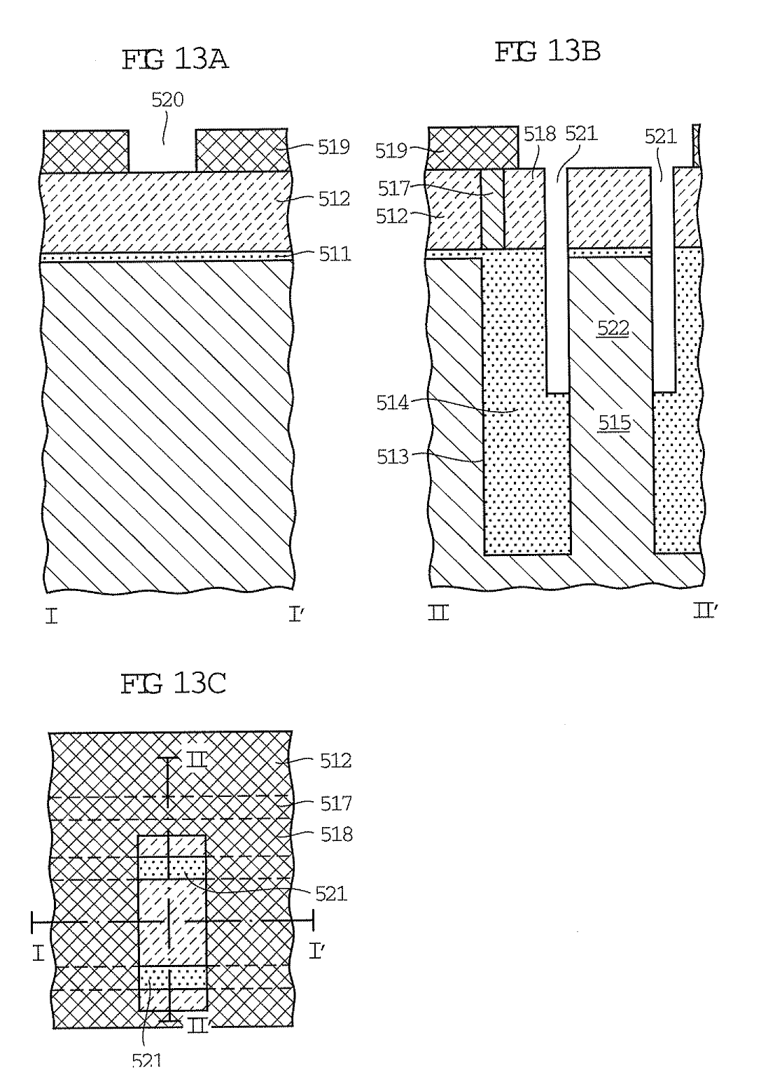

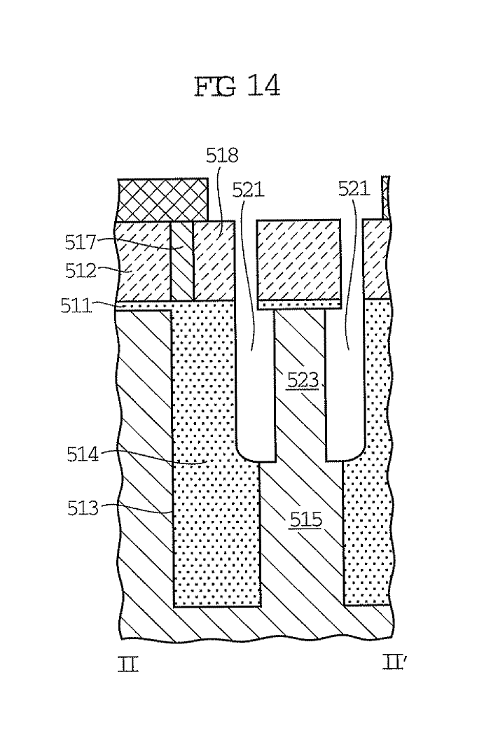

FIGS. 6A and 6B illustrate plan views of an integrated circuit according to embodiments of the invention. As can be seen from FIGS. 6A and 6B, active areas 110, 210, 310, 515, 716 are formed in a semiconductor substrate. The terms “wafer”, “substrate” or “semiconductor substrate” used in the following description may include any semiconductor-based structure that has a semiconductor surface. Wafer and structure are to be understood to include silicon, silicon-on-insulator (SOI), silicon-on sapphire (SOS), doped and undoped semiconductors, epitaxial layers of silicon supported by a base semiconductor foundation, and other semiconductor structures. The semiconductor need not be silicon-based. The semiconductor could as well be silicon-germanium, germanium, or gallium arsenide.

For example, the active areas 110, 210, 310, 515, 716 may be defined by forming corresponding isolation trenches 111, 211, 311, 513, 714 which are filled with an insulating material. The isolation trenches 111, 211, 311, 513, 714 electrically insulate adjacent active areas from each other. Although in FIGS. 6A and 6B the active areas are illustrated so as to extend as continuous lines it is clearly to be understood that they may have any arbitrary shape. For example, the active areas may be formed as segmented active areas which are isolated from each other by appropriate isolation devices. Examples of isolation device include isolation trenches, trench capacitors, isolation field effect transistors which are commonly known in the art. As is illustrated in FIG. 6A, the longitudinal direction of the active areas may extend in a first direction 11. As is illustrated in FIG. 6B, the longitudinal direction of the active areas may extend in a direction which is slanted with respect to the first direction 11. Accordingly, the longitudinal direction of the active areas may be different from the direction of the bitlines and the wordlines.

As will be explained hereinafter, an integrated circuit, may include a FinFET of a first type having a first gate electrode and a FinFET of a second type having a second gate electrode, wherein the first gate electrode is formed in a gate groove that is defined in a semiconductor substrate and wherein a bottom side of a portion of the second gate electrode is disposed above a main surface of the semiconductor substrate.

In one or more embodiments, the term “main surface” of the semiconductor substrate relates to the planar surface of the substrate or of the wafer, for example the surface into which the respective processes are to be performed. The term “vertical” relates to a direction which extends downward or upward at an angle of 70 to 100° (degrees) from the planar surface of the substrate. The term “horizontal” relates to a direction which extends substantially parallel to the planar surface of the substrate, for example a direction which extends at an angle from −20° to 20° (degrees) from the planar surface of the substrate.

The integrated circuit may further include a planar transistor having a third gate electrode which is formed above the semiconductor substrate. By way of example, portions of first or second gate electrodes are disposed in isolation trenches that are adjacent to semiconductor substrate portions.

According to one embodiment, a bottom surface of the gate groove may be disposed below the main surface of the semiconductor substrate. For example, the bottom surface of the gate groove may be disposed more than 5 nm below the main surface of the semiconductor substrate. According to one embodiment, the first gate electrode includes first vertical portions and the second gate electrode includes second vertical portions, wherein the first and the second vertical portions may extend to the same depth.

According to another embodiment, an integrated circuit, includes a FinFET of a first type having a first gate electrode and a FinFET of a second type having a second gate electrode, wherein the first gate electrode is formed in a gate groove defined in a semiconductor substrate, and a current path between a first and a second contact regions of the FinFET of the second type includes only horizontal components.

According to a further embodiment, a FinFET includes a gate electrode including vertical portions. The FinFET is formed in a semiconductor substrate portion and isolation trenches are adjacent to the semiconductor substrate portion. The vertical portions are self-aligned with respect to the position of the isolation trenches. By way of example, part of the vertical portions may be disposed in the semiconductor substrate. Part of the vertical portions may be disposed in the isolation trenches. By way of further example, the vertical portions may be formed so as to partially extend in the semiconductor substrate as well as in the isolation trenches. According to one embodiment, an integrated circuit may include a FinFET as defined above.

As will be used herein after, the term “FinFET” refers to a field effect transistor having a first and a second source/drain portion. A channel is disposed between the first and second source/drain portions. A gate electrode is insulated from the channel by a gate dielectric. The gate electrode is configured to control the conductivity of the channel. In a FinFET, the channel has the shape of a fin or a ridge. The gate electrode encloses the channel at at least two sides. For example, the gate electrode may enclose the channel at a horizontal side and at least one vertical side. Alternatively, the gate electrode may enclose the channel at two vertical sides with respect to the surface of the substrate.

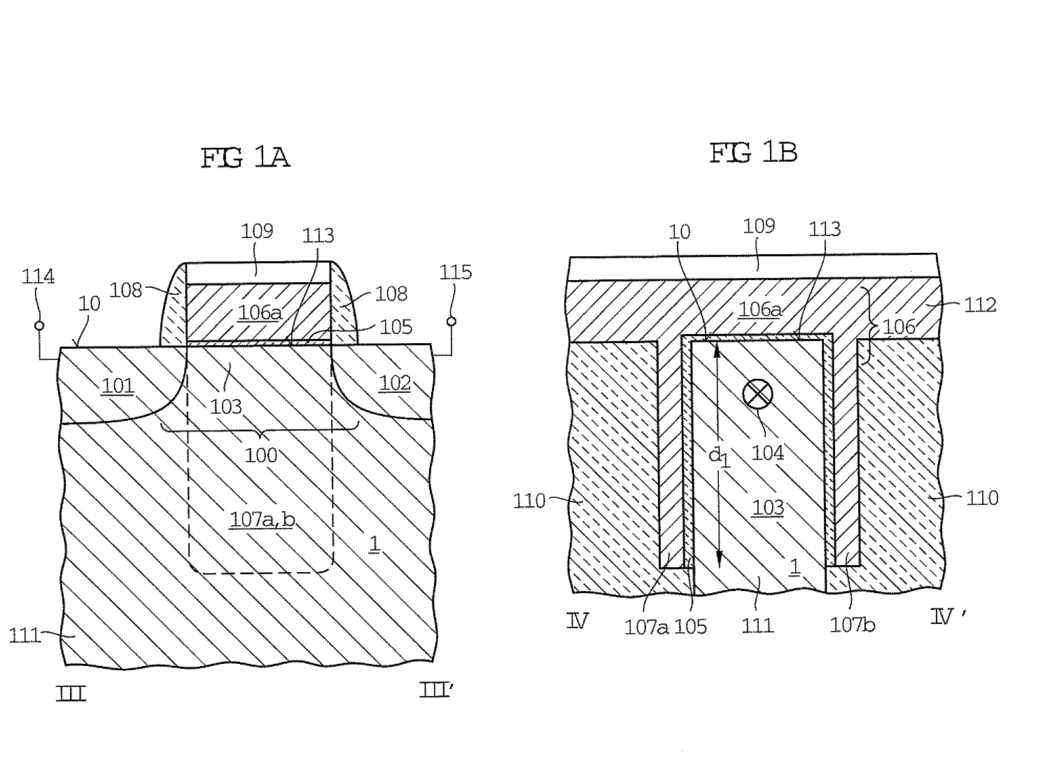

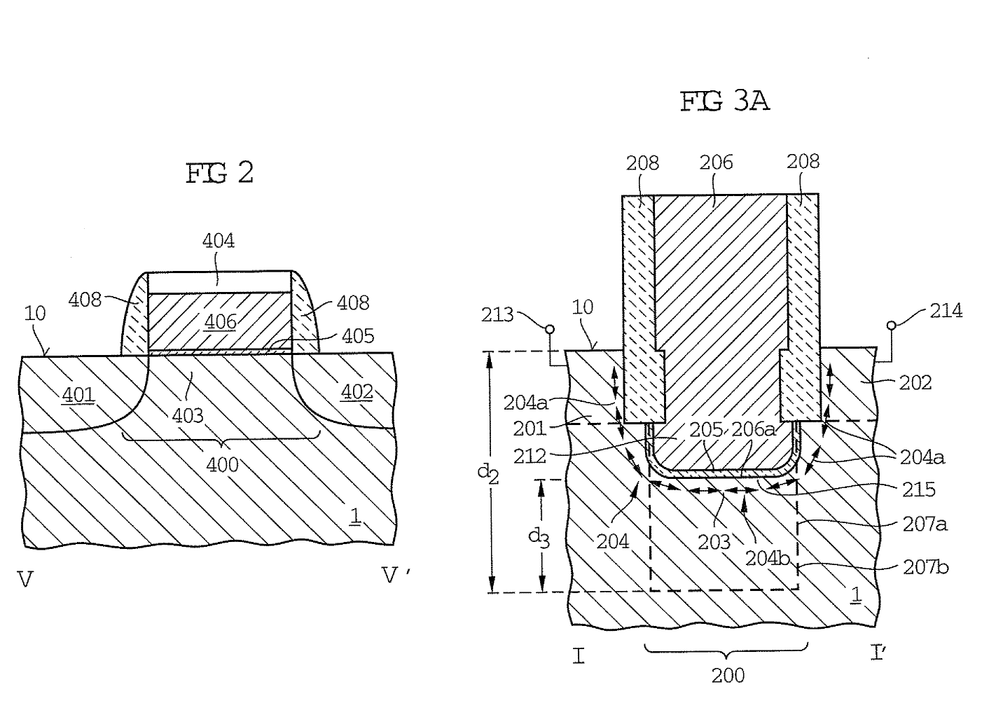

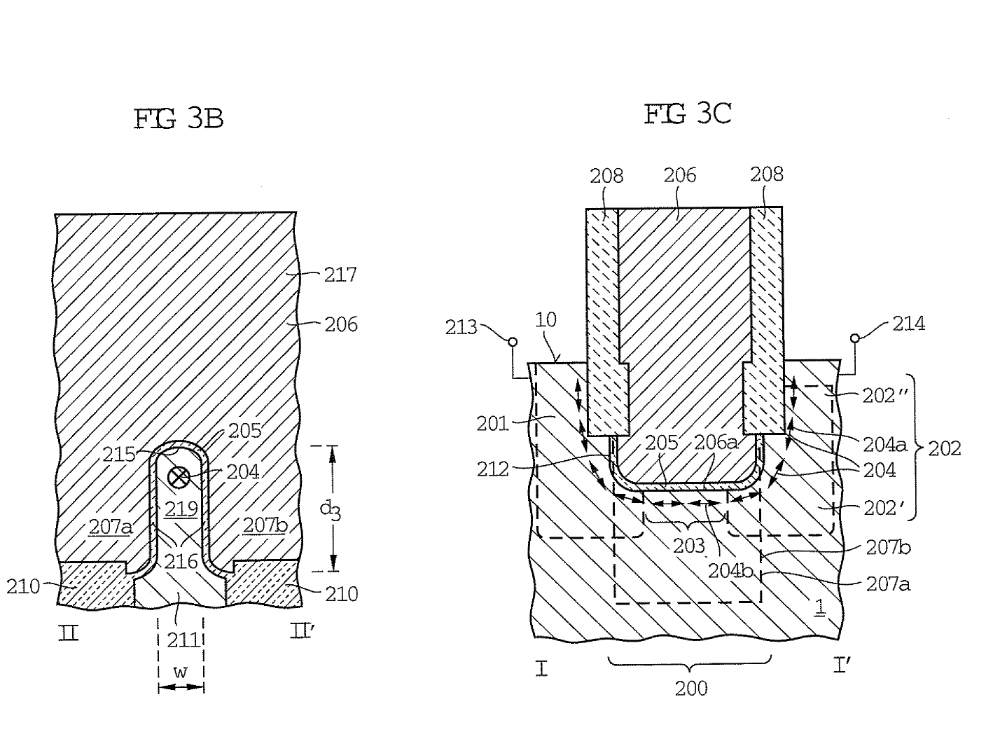

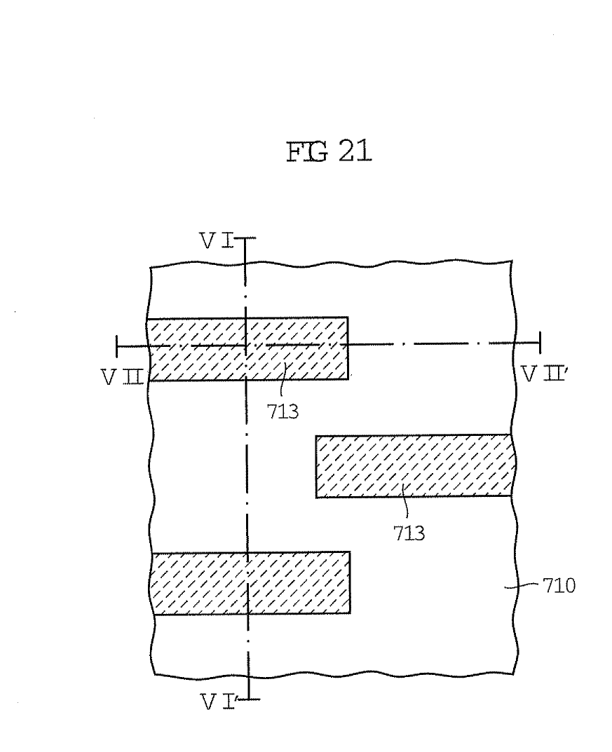

As is illustrated in the following figures, a cap layer such as the layer 109 in FIG. 1A, the layer 404 in FIG. 2 and layer 527 in FIG. 17 may be disposed above the wordlines or the gate conductive material. Nevertheless, as is clearly to be understood, such a cap layer may as well be omitted. Accordingly, such a cap layer is just an optional feature. By way of example, if any of the transistors as described herein below forms part of a logic device such a cap layer may be omitted. Materials of the cap layer include any suitable dielectric materials such as silicon nitride (for example, Si₃N₄) or silicon oxide (for example, SiO₂).

FIGS. 1A and 1B illustrate cross-sectional views of a transistor 100 of the second type. For example, the cross-sectional view illustrated in FIG. 1A is taken between III and III′, whereas the cross-sectional view illustrated in FIG. 1B is taken between IV and IV′ as can be seen from FIGS. 6A and 6B, respectively. As can be seen from FIGS. 1A and 1B, a bottom side of a portion 106a of the gate electrode 106 is disposed above the main surface 10 of the substrate 1. The substrate 1 may be any kind of semiconductor substrate, for example, an n- or a p-doped silicon substrate. The substrate may include any type of laminated or layered structure, for example, an SOI (silicon on insulator) substrate. The gate electrode 106 further includes vertical portions 107a, b, which extend before and behind the drawing plane of FIG. 1A. The transistor 100 further includes a first and a second doped portions 101, 102. By way of example, the first and the second portions 101, 102 may be p- or n-doped. A channel 103 is formed between the first and the second doped portions 101, 102. The gate electrode 106 is insulated from the channel 103 by the gate dielectric 105. For example, the gate dielectric 105 may be made of any suitable insulating material such as silicon oxide, silicon nitride and others. A cap layer 109 may be disposed on top of the gate electrode 106. Sidewall spacers 108 may be formed laterally adjacent to the gate electrode 106. The channel 103 extends along the surface 10 of the substrate 1. A first contact region 114 is provided so as to electrically connect the first source/drain portion 101 with a corresponding bitline, for example. A second contact region 115 is provided which may optionally electrically connect the second source/drain portion 102 with a storage element (not illustrated). The second contact region 11 may alternatively be connected with an arbitrary element, for example, a conductive line. For example, the transistor may be a “floating-body” transistor which is configured to store a charge.

A current path between the first and the second contact regions 114, 115 includes the channel 103 as well as the distance from the contact regions 114, 115 to the metallurgical boundary between the source/drain portion 101, 102 and the channel 103.

According to one embodiment, the current path between the first and the second contact regions 114, 115 may only include horizontal components, for example, components which extend parallel to the substrate main surface.

FIG. 1B illustrates a cross-sectional view which is taken perpendicularly with respect to the cross-sectional view of FIG. 1A. As can be seen, the vertical portions of the gate electrode 107a, 107b laterally enclose the channel 103 so that the channel portion 103 is enclosed at three sides thereof by the gate electrode 106. The gate electrode 106 is insulated from the channel portion 103 by the gate dielectric 105. As is illustrated in FIG. 1B, the vertical portions 107a, 107b may be formed so as to be disposed in the isolation trenches 110. Nevertheless, as will be explained later, the vertical portions 107a, 107b may also extend in the active area 110. The surface 113 of the channel portion 103 is essentially disposed at the same height as the main surface 10 of the substrate 1. In this respect, the term “essentially at the same height” means that the top surface 113 of the channel region 103 may be slightly recessed with respect to the main surface 10, i.e. by an amount of less than 1 nm. This slight recess may be due to an oxidation process by which the gate dielectric 105 is formed. This oxidation process may consume some of the substrate material so as to slightly recess the surface 113 of the channel 103.

The transistor illustrated in FIG. 1B is referred to as a FinFET since the substrate portion, in which the channel is formed, has the shape of a fin or a ridge. Three sides of the fin are enclosed by the gate electrode 106. Accordingly, in case the transistor is a depletion-mode transistor, the FinFET may be fully depleted when the gate electrode 106 is correspondingly activated. In this regard, the transistor may as well be an enhancement-mode type transistor as an alternative. Several gate electrodes 106 of adjacent transistors may be connected via the wordlines 112 which may extend perpendicularly with respect to the direction of the active areas and the isolation trenches. Nevertheless, the wordlines 112 may also extend in a direction which is not perpendicular with respect to the direction of the active areas and the isolation trenches.

FIG. 2 illustrates a cross-sectional view of a transistor 400 of a third type which is taken between V and V′ as can be seen from FIGS. 6A and 6B, respectively. The transistor 400 illustrated in FIG. 2 includes a first and a second source/drain portions 401, 402. The first and second source/drain portions 401, 402 may be formed as doped portions in the substrate 1. The channel 403 is disposed between the first and the second source/drain portions 401, 402. The gate electrode 406 is disposed on top of the substrate main surface 10. The gate dielectric 405 is disposed between the gate electrode 406 and the channel 403. A capping layer 404 may be disposed on top of the gate electrode 406. Sidewall spacers 408 may be laterally adjacent to the gate electrode 406. The top surface of the channel 403 is essentially at the same height as the main surface 10 of the substrate 1. The transistor illustrated in FIG. 2 corresponds to the planar transistor, which is generally well known.

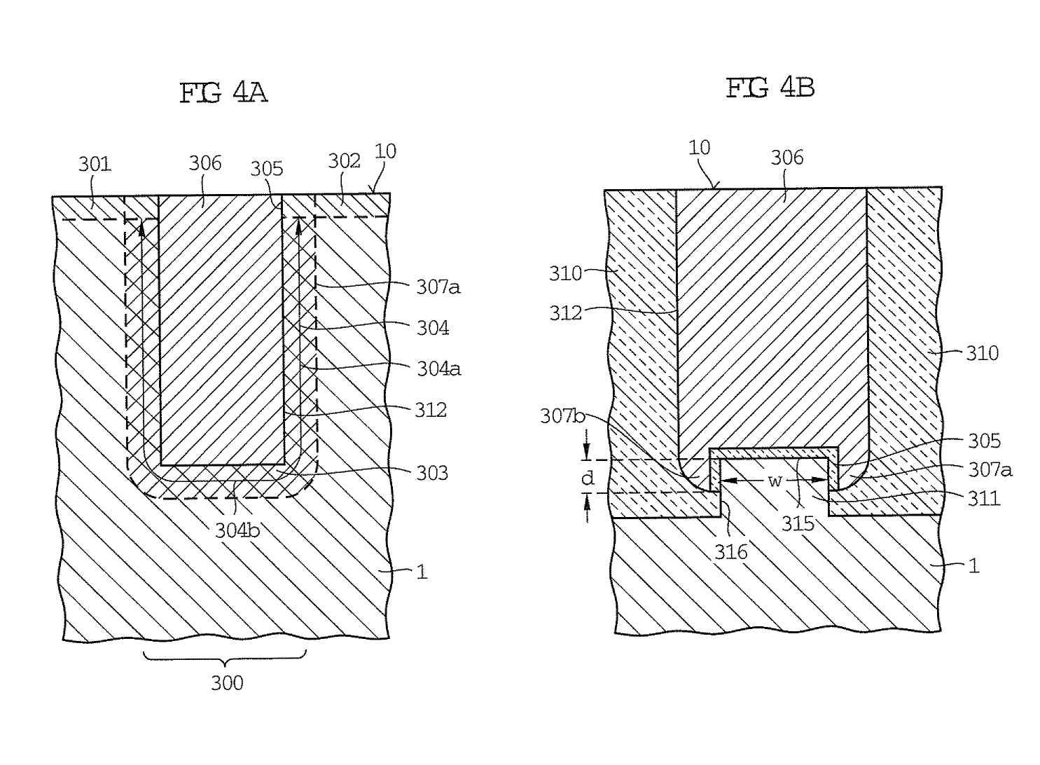

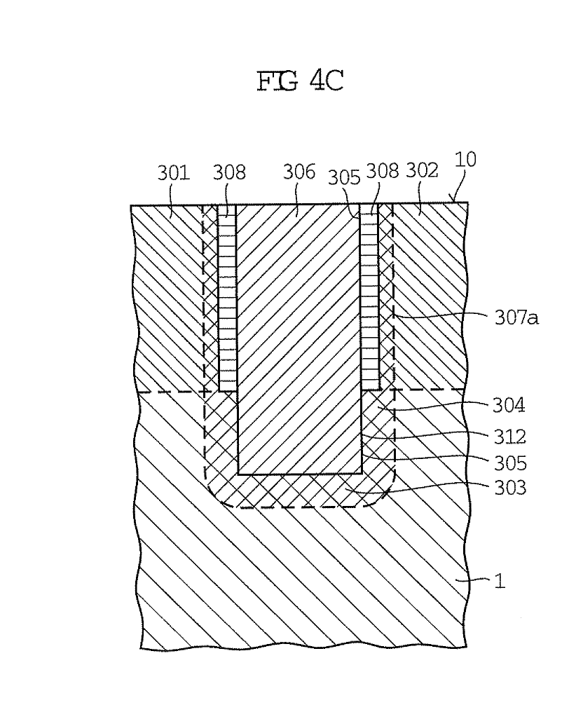

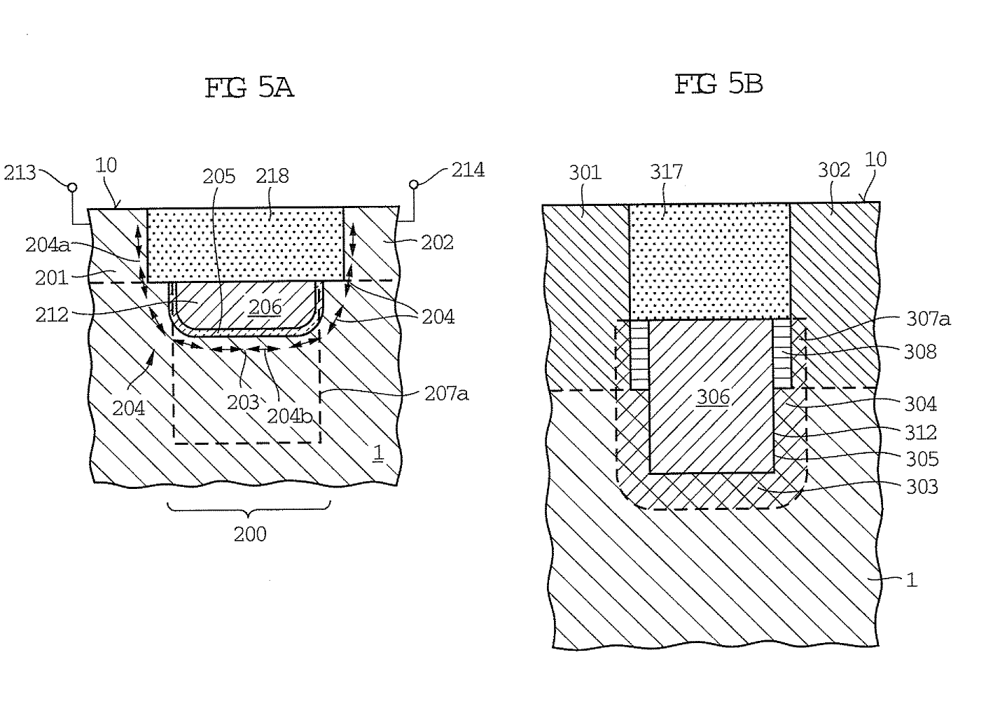

FIGS. 3A to 3C illustrate cross-sectional views of a first type of a FinFET. For example, the cross-sectional views of FIG. 3A to 3C may be taken between I and I′ and II and II′, respectively. The transistor 200 includes a first and a second source/drain portions 201, 202 and a channel 203 which is disposed between the first and the second source/drain portions 201, 202. The conductivity of the channel 203 is controlled by the gate electrode 206. The active area 211 has the shape of a fin or a ridge and three sides of the fin are enclosed by the gate electrode 206.

The first and the second source/drain portions 201, 202 are disposed in the main surface region of the semiconductor substrate 1. The gate electrode 206 is disposed in a gate groove 212. The gate electrode 206 further includes two vertical portions 207a, b. The gate groove 212 is etched in the substrate surface 10. Accordingly, a top portion 215 of the active area 211 is disposed below the main surface 10 of the semiconductor substrate 1. The bottom side of the central portion 206a of the gate electrode is disposed below the main surface 10. The vertical portions 207a, b extend in a plane which lies before and behind the depicted cross-section and therefore are illustrated with broken lines in FIGS. 3A and 3C. The gate electrode 206 is insulated from the channel 203 by the gate dielectric 205. A sidewall spacer 208 having a thickness which is larger than the thickness of the gate dielectric 205 may be disposed between the gate electrode 206 and the first and the second source/drain portions 201, 202, respectively. By way of example, the sidewall spacer 208 may be made of silicon nitride. A first contact region 213 is provided so as to electrically connect the first source/drain portion 201 with a corresponding bitline, for example. A second contact region 214 is provided so as to electrically connect the second source/drain portion 202 with a storage element (not illustrated).

The gate electrode 206 may be made of any conductive material, for example, polysilicon. The first and second source/drain portions 201, 202 may be implemented as normally or heavily doped silicon regions and, consequently, exhibit an excellent electrical conductivity. The channel 203 is lightly p-doped or lightly n-doped and therefore insulates the first from the second source/drain portions unless a suitable voltage is applied to the gate electrode 206.

A current path between the first and the second contact regions 213, 214 may include a first component 204a which extends in a first vertical direction, for example, downwards, a second component 204b which extends in a horizontal direction, and a third component 204a extending upwards, in a vertical direction which is opposite to the first vertical direction. Differently stated, the current path includes the channel 203 as well as the distance from the contact regions 213, 214 to the metallurgical boundary between the source/drain portion 201, 202 and the channel.

Accordingly, a current flow from the first to the second contact region 213, 214 may first have a weakly gated vertical path, thereafter, a strongly gated vertical path, followed by a strongly gated horizontal path, a strongly gated vertical path and, thereafter, a weakly gated vertical path, the term “thereafter” referring to the positional or spatial relationship. Accordingly, since the current path includes a portion extending in a recess which is formed in the substrate surface 10, a minimum distance between the heavily doped first and second source/drain portions 201, 202 may be increased in comparison with a FinFET of the second type. As a consequence, an electrical field at the source/drain portion-channel junction and consequently a leakage current may be reduced. The heavily doped portions 201, 202 may be separated from the gate electrode 206 by the spacer portion 208. Accordingly, an influence of the electrical field of the gate electrode 206 on the heavily doped portions 201, 202 may be reduced.

FIG. 3B illustrates a cross-section of the transistor of the first type in a direction perpendicular to the direction of FIG. 3A. For example, there is illustrated a section across the fin region 219 of the active area, for example, a portion of the active area having a narrow width, the fin region 219 being surrounded on three sides thereof by the gate electrode 206. In the fin region 219 the active area has the form of a ridge or a fin. The active area has a top side 215 and two lateral sides 216, wherein the length of the top side 215 may be smaller than the length of the lateral sides 216.

In FIG. 3B, the vertical portions 207a, 207b are disposed along the lateral sides 216 of the ridge, whereas the gate groove 212 in which the gate electrode 206 is formed, is disposed along the top side of the ridge 215. The gate electrode 206 is insulated from the fin region 219 by the gate dielectric 215. As can be seen from FIG. 3B, the current path 204 is in a direction perpendicular to the plane depicted in FIG. 3B.

Due to the narrow width of the fin region, the transistor body can be fully depleted, so that the sub-threshold slope of the transistor can be improved. As a consequence, an improved on-current/off-current ratio is obtained. According to one embodiment of the invention, the fin region may be locally thinned so that the width of the channel region is made smaller than the width of the first and second source/drain portions 201, 202. As a consequence, the off-current of the transistor may be further improved with respect to the known transistor while the contact area of the source/drain portions is not decreased. As a result, the contact resistance may not be increased.

In the structure illustrated in FIGS. 3A, 3B, the length L_{eff} of the channel corresponds to the distance between the first and second source/drain portions. In addition, the width of the channel corresponds to the width of the region in which the conductivity of the channel is controlled by the gate electrode 206. By way of example, the height of the fin d₃ may be 20 to 100 nm, and the fin width w may be less than 35 nm. Further, the height of the fin d₃ may be the same as the height of the fin d₁ of the transistor of the second type illustrated in FIGS. 1A and 1B, respectively.

Accordingly, the transistor of the first type provides an improved on-current in comparison with known transistors, since the width of the channel is increased, whereby the resistance is reduced. The transistor has a larger slope of the sub-threshold characteristics and a remarkably reduced body effect. Thereby, the on-current is further increased. Furthermore, the transistor additionally provides an improved off-current due to its larger channel length.

In summary, the transistor of the first type as illustrated in FIGS. 3A and 3B combines an improved on-current with a decreased off-current.

The vertical portions 207a, 207b of the transistor of the first type may extend to a depth d2, which may be equal to the depth d1 of the vertical portions 107a, 107b of the transistor of the second type. In this respect, the depth of the vertical portions is defined by the depth measured from the main surface 10 to the bottom portion of the vertical portions, respectively. For example, the depth of the vertical portions may be more than 20 nm, for example, more than 50 nm.

FIG. 3C illustrates a modification of the transistor of the first type as illustrated in FIG. 3A. In FIG. 3C, the second source/drain portion 202 includes a heavily doped portion 202″ and a lightly doped portion 202′. The lightly doped portion 202′ may extend to the same depth as the first source/drain portion 201. By providing the lightly doped portion 202′ between the heavily doped portion 202″ and the channel 203, the electrical field may be reduced. Accordingly, a junction leakage current may be reduced.

Generally speaking, the leakage current corresponds to the current flow from the storage element to the first source/drain portion or the silicon body, when the gate electrode is not addressed. Since the electrical field at the second source/drain portion-channel junction highly influence the leakage current, it is advantageous to reduce the electrical field at the second source/drain portion-channel junction. By reducing the leakage current, the retention time, i.e. the time during which an information is recognizably stored in the memory cell, may be increased.

Accordingly, the transistor of the first type may include an asymmetric arrangement of the first and second source/drain portions such as illustrated in FIG. 3C, in which the second source/drain portion 202 includes a lightly and a heavily doped portion 202′ may extend to the same depth as the first source/drain portion 201. Also the first source/drain portion 201 may include a lightly and a heavily doped portion and the lightly doped portion may be arranged between the heavily doped portion and the channel region. For example, the first and second source/drain portions having lightly and heavily doped portions may be arranged in a symmetric manner.

According to the embodiment illustrated in FIG. 3C, the lower side of the lightly doped second source/drain portion 202′ is disposed beneath the lower edge of the gate groove 202 or beneath the top side of the fin portion 215. As a consequence, the effective width of the second source/drain portion may be remarkably increased. Since this width determines an on-current, the on-current characteristics of the transistors may be further improved.

The heavily doped second source/drain portion 202″ which will later be connected with a storage element is shielded from the gate electrode by the spacer 208. Accordingly, the electrical field at the junction between the second source/drain portion 202″ and the channel will be reduced. As a consequence, the retention time may further be increased.

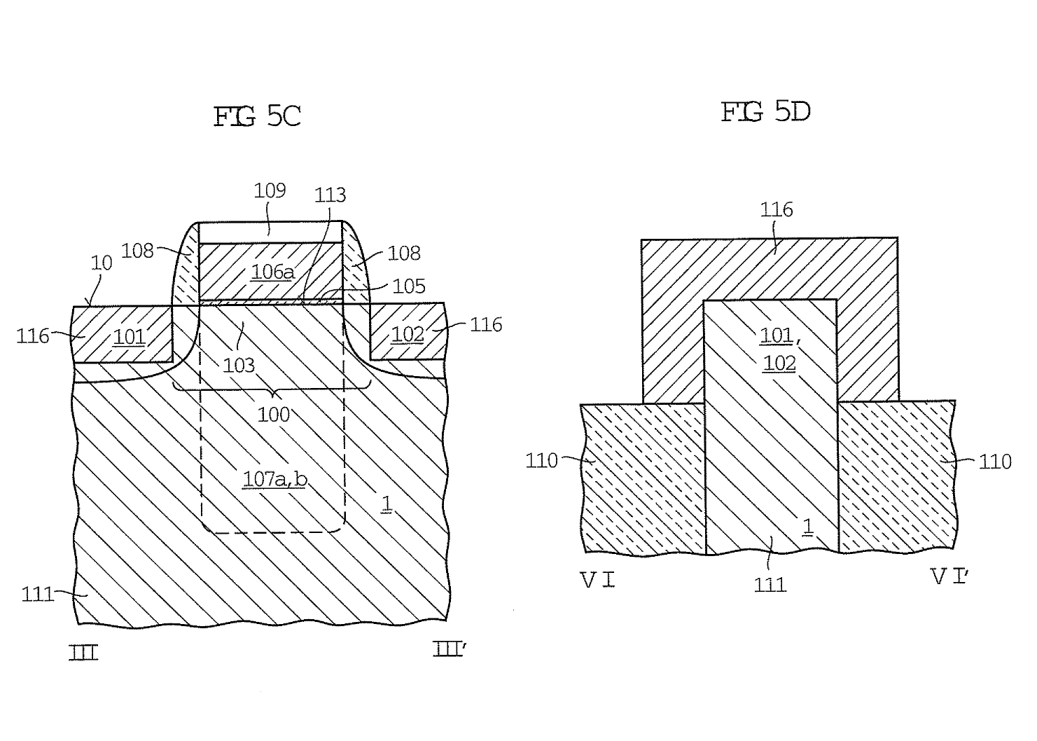

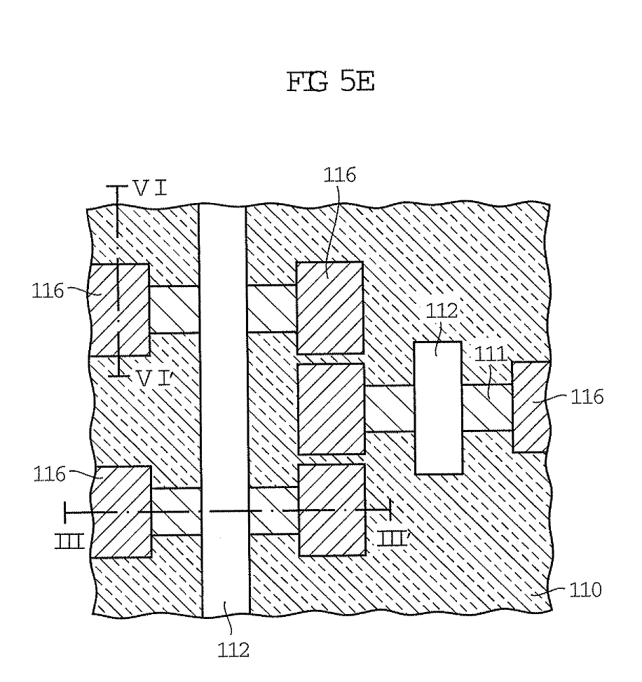

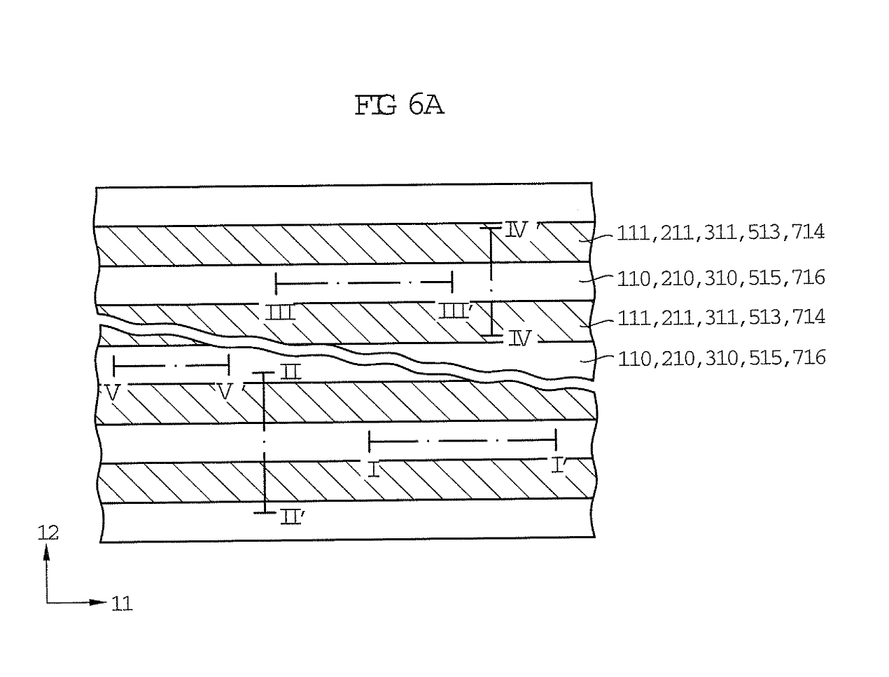

The transistor described with respect to FIGS. 3A to 3C may be modified in several ways. For example, as is illustrated in FIGS. 4A to 4C, the gate electrode 306 may be formed in a gate groove 312 which is formed in the semiconductor substrate 1. The vertical portions 304a, b of the gate electrode may only extend slightly deeper into the substrate than the gate groove 312. For example, as is illustrated in FIG. 4B, the vertical portions 307a, b extend to a depth of approximately less than 25 nm measured from the bottom portion of the gate groove 321 which is formed in the substrate material. Differently speaking, the depth d corresponds to the depth of the vertical portions 307a, b being measured from the top surface 315 of the fin-like portion. The channel which is adjacent to the gate electrode 306 may not be narrowed with respect to the active area which is defined by forming the isolation trenches 310. Accordingly, when applying a typical gate voltage, the channel may not be fully depleted. Nevertheless, as can for example be taken from FIG. 4B, the resulting transistor 300 has an increased channel width in comparison with the conventional recessed channel transistor.

The transistor 300 illustrated in FIG. 4A includes a first and a second source/drain portions 301, 302. The gate electrode 306 is formed in a gate groove 312 and includes vertical portions 304a, 304b. Accordingly, a channel 303 is formed between the first and the second source/drain portions 301, 302. The current path 304 includes horizontal portions 304b as well as vertical portions 304a. In the transistor illustrated in FIG. 4A, the first and second source/drain portions 301, 302 may extend to a depth which is deeper than the depth which is indicated in this Figure. For example, they may extend to below the bottom of the gate groove 312. A sidewall spacer made of a suitable insulating material 308 may be disposed between the first and the second source/drain portions 301, 302 and the gate electrode 306, respectively.

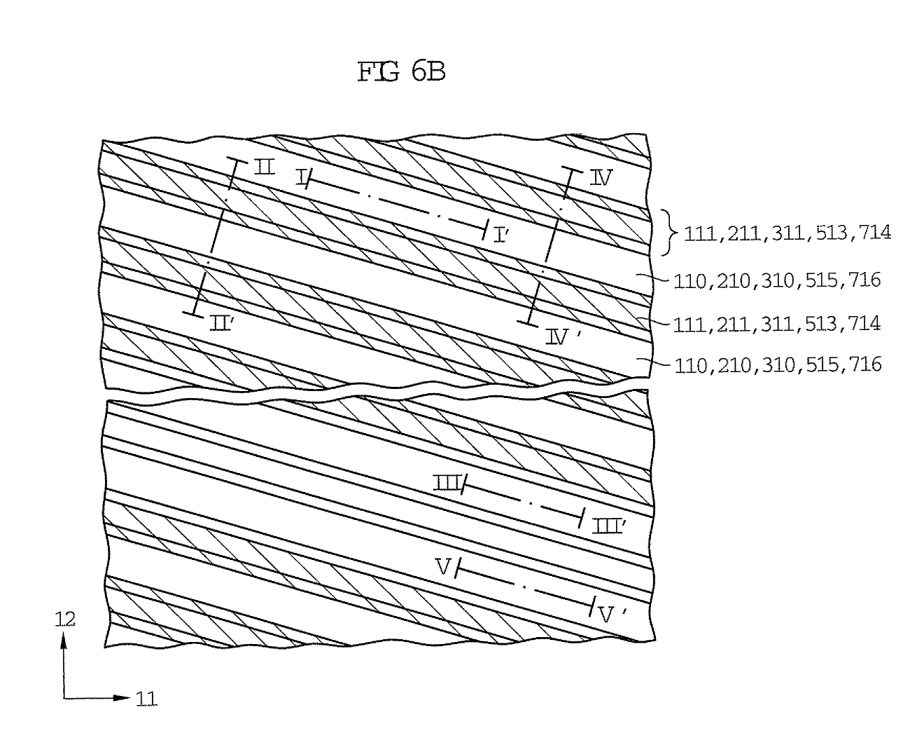

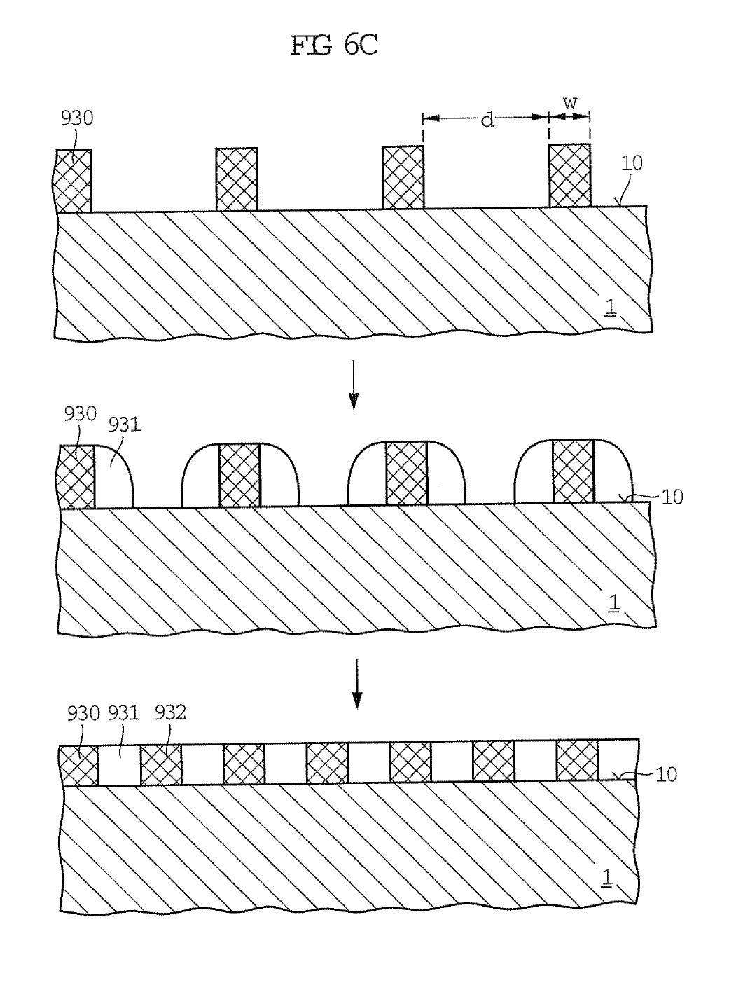

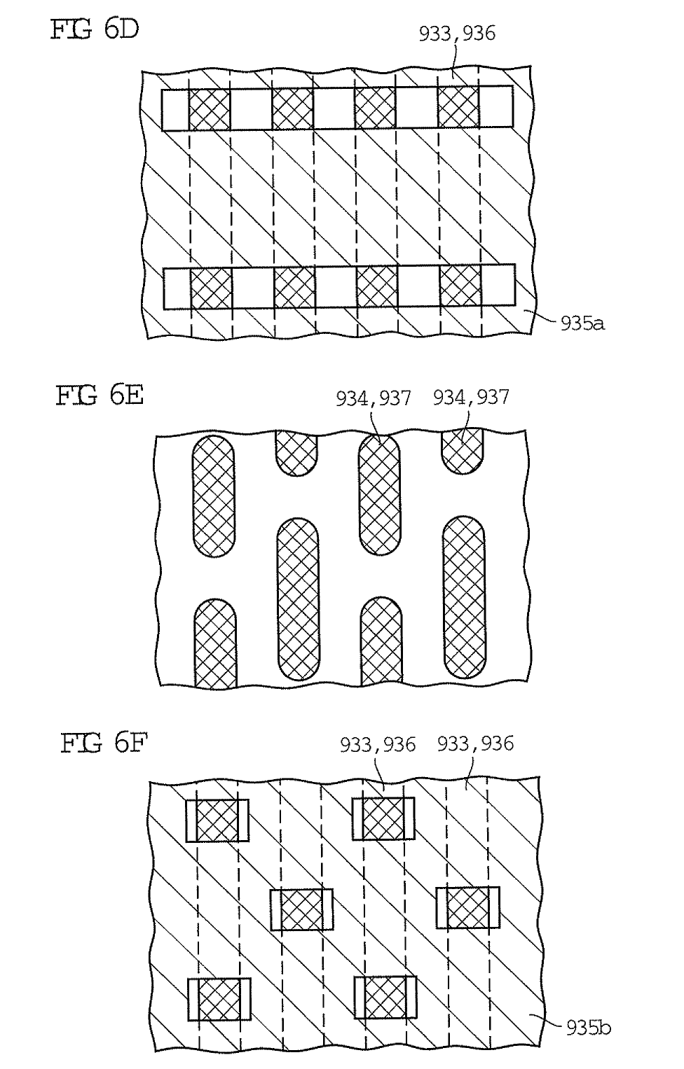

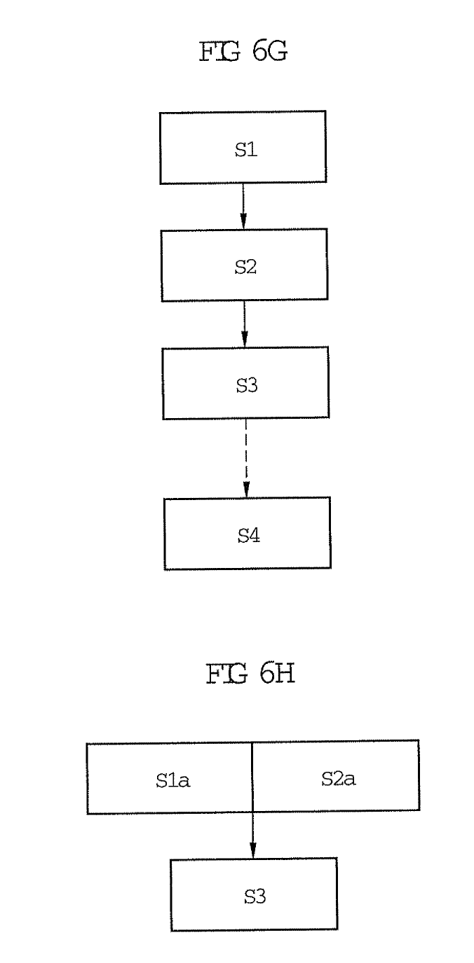

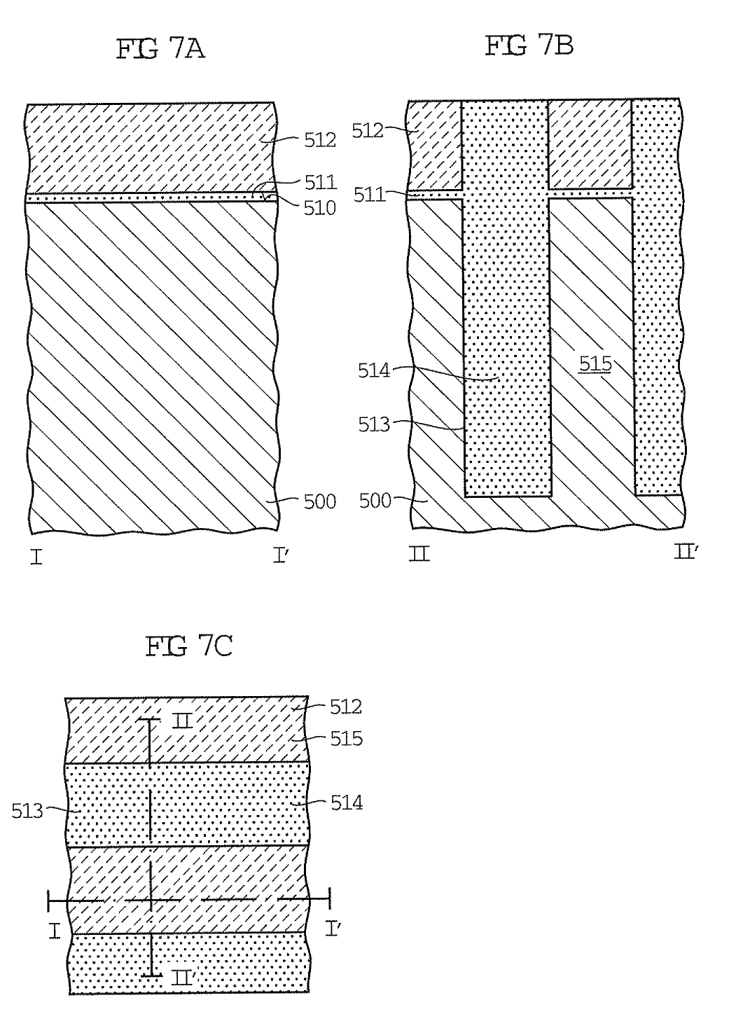

The transistors illustrated in FIGS. 3 and 4 may be further modified in any arbitrary manner. By way of example, the top surface of the gate electrode 306, 206, may be disposed beneath the main surface 10. For example, as is illustrated in FIGS. 5A and 5B, respectively, an insulating material 218, 317 may be disposed above the corresponding gate electrodes and wordlines so as to insulate the gate electrodes from the portions lying above. This concept which is referred to as the buried wordline concept may of course be implemented with the transistors illustrated in FIGS. 3 and 4, respectively.

In any of the examples illustrated throughout this specification, the transistor may include special contacts which may be wrapped around the source/drain portions. For example, FIG. 5C illustrates a cross-sectional view of the transistor which is also illustrated in FIG. 1A, including these special contacts. As is illustrated in FIG. 5C, a conductive material may be formed so as to wrap around the source/drain portions 101, 102. Accordingly, as is illustrated by broken lines, wrap-around contacts 116 are defined before and behind the depicted plane of the drawing. FIG. 5D illustrates a cross-sectional view across any of these contacts, the view of FIG. 5D being taken perpendicularly with respect to the cross-sectional of FIG. 5C. As can be seen, the conductive material 116 may be formed so as to enclose the source/drain portion 101, 102 at three sides thereof By way of example, the layer 116 may be formed as a conformal layer. Nevertheless, it may also be formed as a non-conformal layer.

FIG. 5E illustrates an exemplary plan view of a transistor array including these special contacts. As can be seen, the area of the contacts 116 is increased with respect to the diameter of the active area 111. Such a wrap-around contact 116 may be formed as follows. After further processing the transistor array, usually one or more dielectric layers are deposited. For example, a silicon nitride liner may be deposited, followed by a silicon oxide layer. Thereafter, openings are formed so as to uncover the source/drain portions. Thereafter, a suitable conductive material is filled into the openings so as to form the wrap-around contacts 116. By way of example, the conductive material may be any of the materials which are commonly used for defining the gate electrode. Specific examples include metals or polysilicon or metal compounds. For example, a titanium, tantalum or titanium nitride or tantalum nitride layer may be deposited, followed by a tungsten layer. Alternatively, any suitable metal silicide such as TiSi or TaSi may be deposited, optionally followed by a tungsten layer. As a result, the wrap-around contact 116 as is, for example, illustrated in FIG. 5D may be formed.

In an integrated circuit having the transistor of the second type as illustrated in FIGS. 1A and 1D, for example, and the transistor of the first type illustrated in any of FIGS. 3A to 5B respectively as well as, optionally, a transistor of a third type illustrated in FIG. 2 the characteristics of each of the transistors can be adjusted in accordance with the specific location of the transistor and the functional requirements of the system. Accordingly, depending on the specific application, transistors having the desired characteristics can be combined on one single semiconductor chip. The integrated circuit or semiconductor chip which has been described herein before, having FinFETs of the first and second types and, optionally, transistors of the third type can be applied in logic products, such as a CPU (“central processing unit”) in DSP chips (“digital signal processor”) or a data processing system. For example, these products may be used in personal computers, notebooks, PDAs (“personal digital assistant”), wherein low power and high speed are extremely important.

Due to the special manufacturing process which will be explained herein below, the transistors of the first type, of the second type and, optionally, of the third type may be formed so as to include gate electrodes which are made of the same layer or layer stack. Accordingly, each of the gate electrodes may be made of an identical layer or layer stack having the same thickness. Each of the transistors may further include a channel having a width which is smaller than the width of each of the source/drain portions. In this context, the width of the channel as well as the width of the source/drain portions is measured in a direction which is perpendicular to the direction of a current flow of the transistor, for example, a direction which connects the first and the second source/drain portions.

The integrated circuit may be implemented as a memory device having an array portion in which a plurality of memory cells are disposed and a support portion. The support portion may include the peripheral portion as well as the core circuitry having circuitry for addressing, writing and reading an information to and from the memory cells. By way of example, the transistor of the first type may be disposed in the array portion. The transistor of the second type as well as the transistor of the third type may be disposed in the support portion and may, for example, form part of the core circuitry or the peripheral circuitry. Nevertheless, the transistor of the second type or the transistor of the third type may as well be disposed in the array portion. The transistor of the first type may as well be disposed in the support portion. The integrated circuit according to one embodiment may be a semiconductor device, for example, an embedded DRAM device, having a memory portion in which memory cells including FinFETs of the first type are disposed. The semiconductor device may further include logical circuits including transistors of the second type and, optionally, transistors of the third type. Nevertheless, the transistor of the second type or the transistor of the third type may as well be disposed in the memory portion. The logical circuits may as well include the transistor of the first type. As is clearly to be understood, the scope of embodiments of the invention also includes semiconductor wafers, in which the integrated circuits as described above are formed.

In the following, an exemplary embodiment of the method of manufacturing an integrated circuit will be described.

As is illustrated in the flow-chart of FIG. 6G illustrating the method according to one embodiment, a method of manufacturing an integrated circuit may include forming a FinFET of a first type (S1) having a first gate electrode and forming a FinFET of a second type (S2) having a second gate electrode, wherein forming the first gate electrode includes defining a gate groove in a semiconductor substrate and filling the gate groove with part of the first gate electrode (S3), and wherein forming the second gate electrode is accomplished so that a bottom side of a portion of the second gate electrode is disposed above a main surface of the semiconductor substrate. According to one embodiment, the method may further include forming a transistor of a third type (S4), the transistor of the third type corresponding to a planar transistor.

For example, forming the first and the second gate electrodes may include defining first and second openings for forming first and second vertical portions of the first and second gate electrodes, respectively. According to one embodiment, defining the first and second openings may be accomplished before defining the gate groove. For example, as is illustrated in the schematic flow-chart illustrated in FIG. 6H, the first and second openings may be defined by common etching processes, for example, by etching processes which simultaneously or contemporaneously etch the first and second openings. As is illustrated in FIG. 6H, the etching of the first openings (S1a) and the etching of the second openings (S2a) may be performed by common etching processes.

By way of example, the first and second openings may be defined by etching the semiconductor substrate. According to another embodiment, the first and second openings may be defined by etching insulating material that is disposed in isolation trenches which are adjacent to the semiconductor substrate.

FIGS. 6A and 6B illustrate plan views of a substrate which may be used when performing the method according to one embodiment of the invention. As can be seen, active areas 110, 210, 310, 515, 716 are defined. For example, the active areas may be defined by defining isolation trenches 111, 211, 311, 513, 714 and filling the isolation trenches with an appropriate insulating material. By way of example, the width of the isolation trenches as well as the distance between neighboring isolation trenches may be equal to the minimal structural feature size F, which may be obtained by the technology employed, or a fraction thereof. Likewise, the width of the active areas as well their distance may be F or a fraction thereof, for example F/2, F/3, F/4 and the like. By way of example, F may be 120 nm, 100 nm, 75 nm, 65 nm, 55 nm or less than 40 nm. Various components may be already formed in the semiconductor substrate. For example, isolation structures may be defined in each of the active area lines so as to form single active area segments. By way of example, the isolation structure may be an isolation trench which is filled with an insulating material having for example, silicon oxide, silicon nitride or silicon oxynitride. The insulating filling may include one or more layers. As a further example, isolation field effect transistors may be formed so as to form active area segments. The isolation field effect transistor may be operated in an off-state so as to insulate neighboring active area segments which are assigned to one active area line, from each other. As is clearly to be understood, the isolation structures or the isolation field effect transistors may as well be formed during the following processes. As a further example, capacitor trenches may be formed, segmenting the active area lines 110, 210, 310, 515, 716. Nevertheless, since the specific implementation of the isolation structure can be performed in any arbitrary manner, the following specification will be focused on the formation of the transistors of the first and second types, respectively.

For example, the active areas may be defined by defining isolation trenches, using an arbitrary hardmask layer as a hardmask layer for patterning the substrate material. According to one embodiment, the pitch and, hence, the width of the active areas 515 may be defined so as to have a sub-lithographic value. By way of example, this may be accomplished by double patterning methods. For example, as will be explained with reference to FIG. 6C, a spacer method may be employed so as to reduce the pitch of hard mask lines by an arbitrary value. For example, in a first process, first lines 930 of a hard mask material may be defined. By way of example, these lines 930 may have a width w which is small compared to their distance d. For example, they may have a width w of less than 100 nm, for example, 50 nm and a distance d of more than 100 nm, for example 150 nm. After defining the first lines 930, spacers of a sacrificial material 931 may be formed which are adjacent to either sides of the lines 930. By way of example, the spacers 931 may be formed by conformally depositing a sacrificial material, and, thereafter, performing an anisotropic etching process so as to remove the horizontal portions of the sacrificial material 931. After defining the spacers 931, a further hardmask material is deposited. By way of example, the second hardmask material may be the same as the first hardmask material. For example, the second and the first hardmask material may be silicon nitride and the sacrificial material may be silicon oxide or polysilicon. Nevertheless, the second hard mask material may also be different from the first hard mask material. Thereafter, a planarizing process is performed so as to obtain the structure illustrated in the bottom portion of FIG. 6C. The sacrificial material 931 may be removed by an appropriate etching process, for example. As a result, lines 930, 932 of one or two different materials are obtained, the distance between the lines being smaller than the distance of the first lines 930. A similar structure may be obtained by employing a double lithography method according to which the second lines 932 are photolithographically defined using a mask which may be identical or similar to the mask which has been employed for defining the first lines 930. Nevertheless, the mask for defining the second lines is shifted by half of the distance of the lines so as to position each of the second lines at a position between two adjacent first lines 930.

According to a double spacer method, when performing the method illustrated in FIG. 6C also lines 930 having a width which may be larger may be formed. By way of example, the width may be approximately half the distance or larger. Thereafter, spacers in a similar manner as is illustrated in FIG. 6C are formed. Then, the first lines 930 may be removed, followed by a process of forming second spacers (not illustrated). Thereafter, a fill material may be provided, followed by a planarizing process. As a result, alternating lines of different materials are provided. By removing selected ones of these lines also hard mask lines of a predetermined material and a selected distance and width may be obtained. Nevertheless, the active areas may also be formed by a simple photolithographic process.

As has been mentioned above, the active areas may be formed so as to extend in continuous lines 933 and, thereafter, they may be segmented by performing an additional photolithographic process. By way of example, already the first hard mask lines 930 may be correspondingly patterned. By way of example, first, the first hardmask lines 930 are formed, followed by a lithographic process, using a mask 935a having a lines/spaces pattern which is rotated by 90° or any other angle so as to photolithographically define the position at which the active areas are to be segmented. This is, for example, illustrated in FIG. 6D. FIG. 6E illustrates a case in which the active areas 934 or hardmask portions 937 are photolithographically segmented using a mask having a shape of extended dots so as to define the single segments. FIG. 6F illustrates another mask 935b for segmenting the active area lines 933 or the hard mask lines 930 for forming the active areas, wherein the mask 935b used for defining the positions of the segmentation has a dot-like pattern, the dots being arranged in a checkerboard-pattern.

In the semiconductor substrate, various implants for defining the well portions may have been performed. The isolation trenches may have been defined by correspondingly patterning a suitable hardmask layer, etching the isolation trenches and filling the isolation trenches with an insulating material.

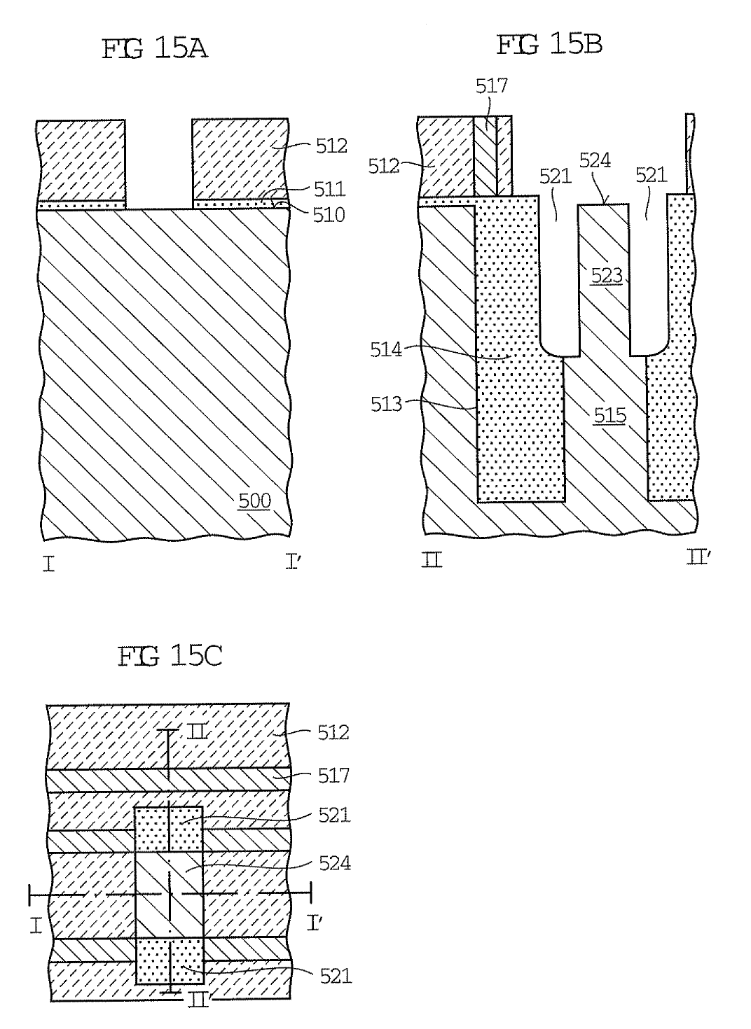

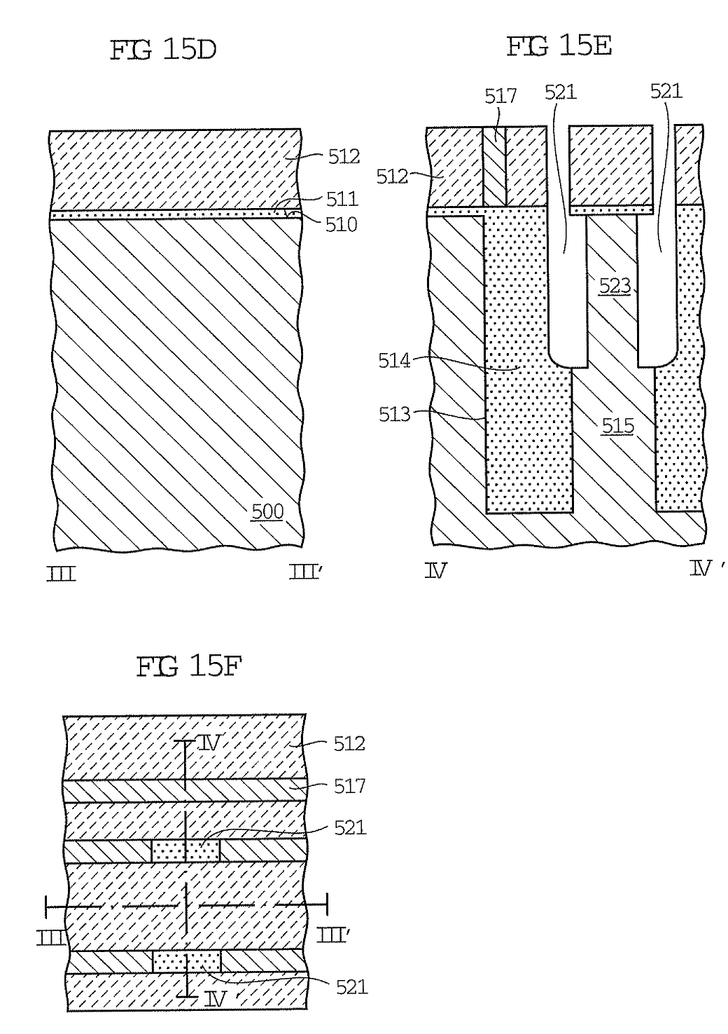

FIG. 7 illustrates views of a workpiece when performing the method according to one embodiment. FIG. 7C illustrates a plan view of the workpiece whereas FIGS. 7A and 7B illustrate cross-sectional views in perpendicular directions, respectively. As is illustrated in FIG. 7A, on top of the main surface 510 of a semiconductor substrate 500, a thin silicon oxide layer 511 as well as a silicon nitride layer 512 having a thickness of approximately 50 to 500 nm may be formed. The cross-sectional view illustrated in FIG. 7A is taken along an active area line 515, whereas the cross-sectional view illustrated in FIG. 7B is taken perpendicularly with respect to the direction of the active area line 515. As is illustrated in FIG. 7B, isolation trenches 513 are formed in the surface 510 of the silicon substrate 500, the isolation trenches 513 being filled with an insulating material 514. The insulating material 514 as illustrated in FIG. 7B may, of course, include several different layers. Nevertheless, for the sake of simplicity, only one insulating material 514 is depicted in FIG. 7B. As is clearly to be understood, several insulating layers may form the insulating material 514, for example, an arbitrary succession of silicon nitride and silicon oxide layers. Between adjacent isolation trenches 513, active areas 515 are formed. The insulating material 514 filled in the isolation trench 513 may be planarized so as to obtain a smooth and planar surface. Thereafter, optionally, an ion implantation process may be performed so as to provide an anti-punch implant. Due to this implantation process, doped portions are provided in the substrate so as to avoid a punch-through between adjacent source/drain portions. FIGS. 8A and 8B illustrate cross-sectional views of the substrate when performing the ion implantation 516. As can be seen, the whole substrate surface is implanted with ions.

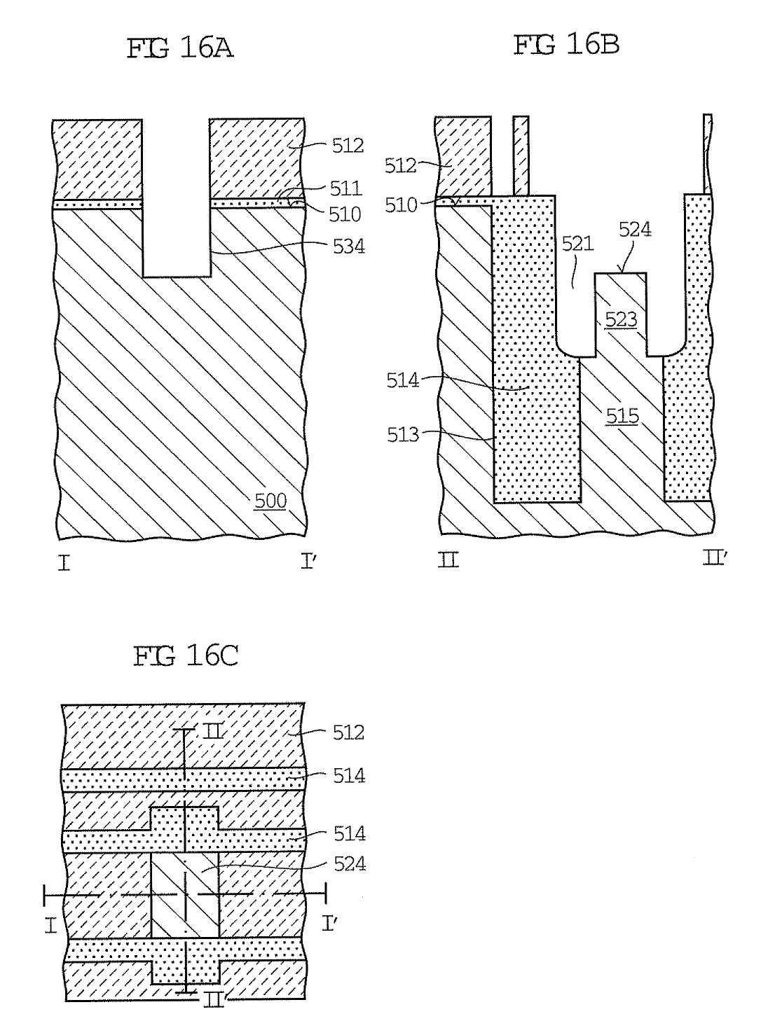

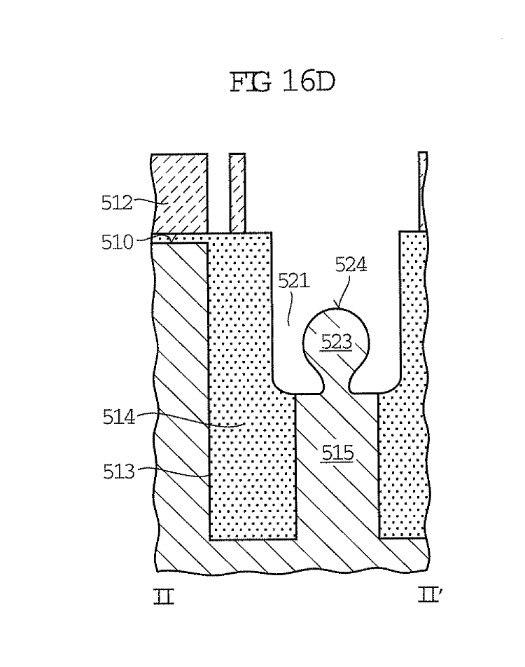

Thereafter, a selective etching process may be performed so as to recess the upper portion of the insulating material 514 filled in the isolation trenches. For example, this recess may be performed by wet or by dry etching. For example, this etching may stop on top of the silicon oxide layer 511. The resulting structure is illustrated in FIG. 9. As can be seen from FIG. 9A, along an active area line 515 the structure remains unchanged. In the direction perpendicular to the active area lines 515, the silicon oxide material 514 is removed from the space between adjacent silicon nitride lines 512. Thereafter, sidewall spacers of a sacrificial material may be formed adjacent to the silicon nitride lines 512. By way of example, the material of the sidewall spacers is chosen so that it can be etched selectively with respect to the material of the lines 512. For example, the sidewall spacers 517 may be made of polysilicon. For forming a sidewall spacer, the sacrificial material may be conformally deposited on the surface, and, thereafter, the horizontal portions of this layer may be removed. For example, this may be accomplished by anisotropical etching. As a consequence, sidewall spacers 517 made of a sacrificial material are formed. The spacers are adjacent to the lines 512 which have been used for defining the active areas 515. Accordingly, the position of the sidewall spacers 517 is aligned with respect to the position of the active areas 515. The resulting structure is illustrated in FIG. 10. As can be seen from the plan view illustrated in FIG. 10B, lines of polysilicon 517 are formed, the lines being adjacent to the lines 512 made of silicon nitride. FIG. 10A illustrates a cross-sectional view of the resulting structure.

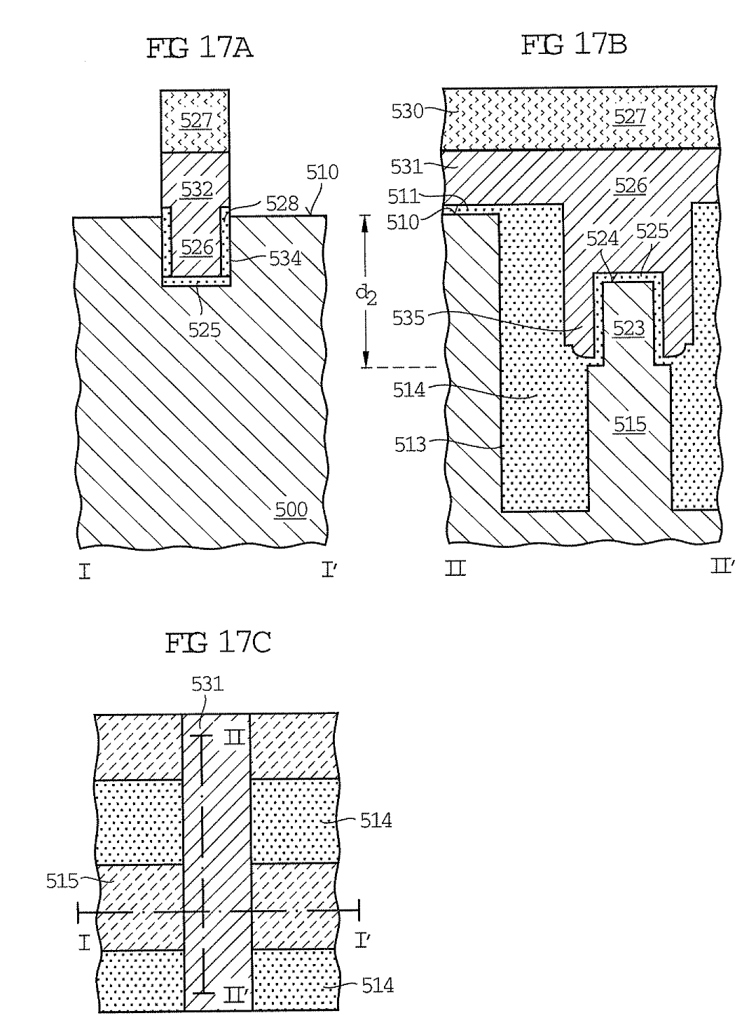

Thereafter, a further fill material 518 is filled in to the spaces between adjacent polysilicon spacers 517. For example, silicon nitride may be filled in these spaces. Then, a CMP (chemical mechanical polishing) process is performed so as to obtain the planar surface. The resulting structure is illustrated in FIG. 11. As can be seen from FIGS. 11A and 11B, lines of silicon nitride are disposed so as to alternate with lines of polysilicon material 517.

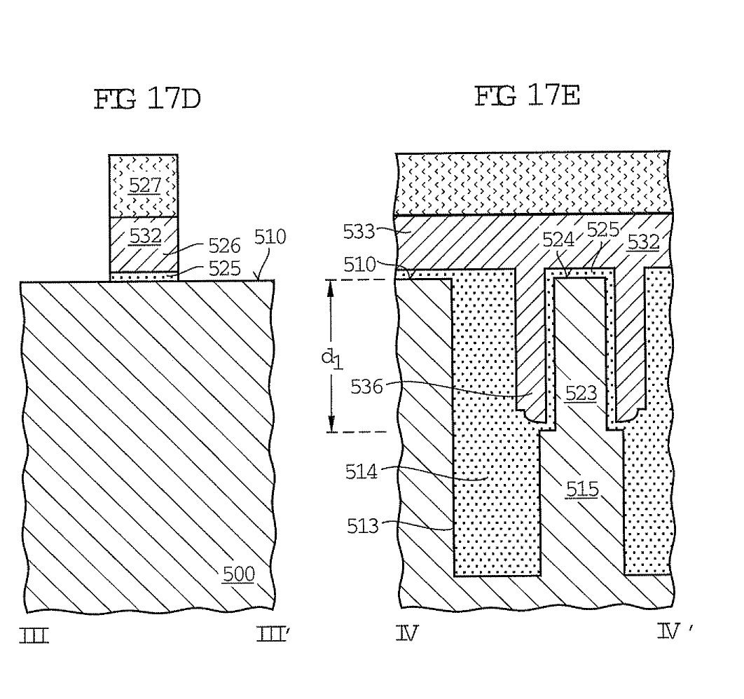

Thereafter, a hardmask layer 519 may be deposited on top of the resulting structure. For example, the hardmask layer may have a thickness of approximately 20 to 500 nm. The material of the hardmask layer may be silicon nitride, silicon oxide, polysilicon, carbon or any combination thereof, for example. The thickness and the composition of the hardmask is selected so that the hardmask layer (stack) may sustain the subsequent etching processes. Then, a photolithographic process is performed so as to open predetermined portions of the hardmask layer 519. By way of example, this may be accomplished by applying a suitable photoresist material and exposing predetermined portions of the photoresist material. For example, a mask having a dot-pattern or a lines/spaces pattern may be used for exposing the photoresist material. After developing the photoresist material, the hardmask layer is patterned so as to form hardmask openings 520. Then, the remaining portions of the photoresist material are removed. The resulting structure is illustrated in FIG. 12. By way of example, FIG. 12C illustrates a position of the hardmask opening 520. As is illustrated in FIG. 12A, a portion of a silicon nitride line 512 is uncovered after opening the hardmask layer. As can be seen from FIG. 12B illustrating a cross-sectional view perpendicularly with respect to the direction of the active areas, some of the silicon nitride spacers 517 are uncovered due to the hardmask opening 520.

Optionally, thereafter, an anti-punch implantation process may be performed in a manner as has been described above.

Thereafter, the spacers 517 made of a sacrificial material may be removed selectively with respect to the lines 512 and the lines 518. For example, this may be accomplished by performing an anisotropic dry etching process which may be selective with respect to the material of the lines 518 and the lines 512. For example, this etching process may be selective to silicon oxide and silicon nitride. Then, an etching process for etching silicon oxide material 514 is performed. For example, this may be accomplished by an anisotropic etching process which may be selective with respect to silicon nitride and silicon. As a result, pockets 521 are formed in the isolation trenches 513, the pockets 521 being adjacent to the active area 515. As a consequence, fin-like substrate portions 522 are provided.

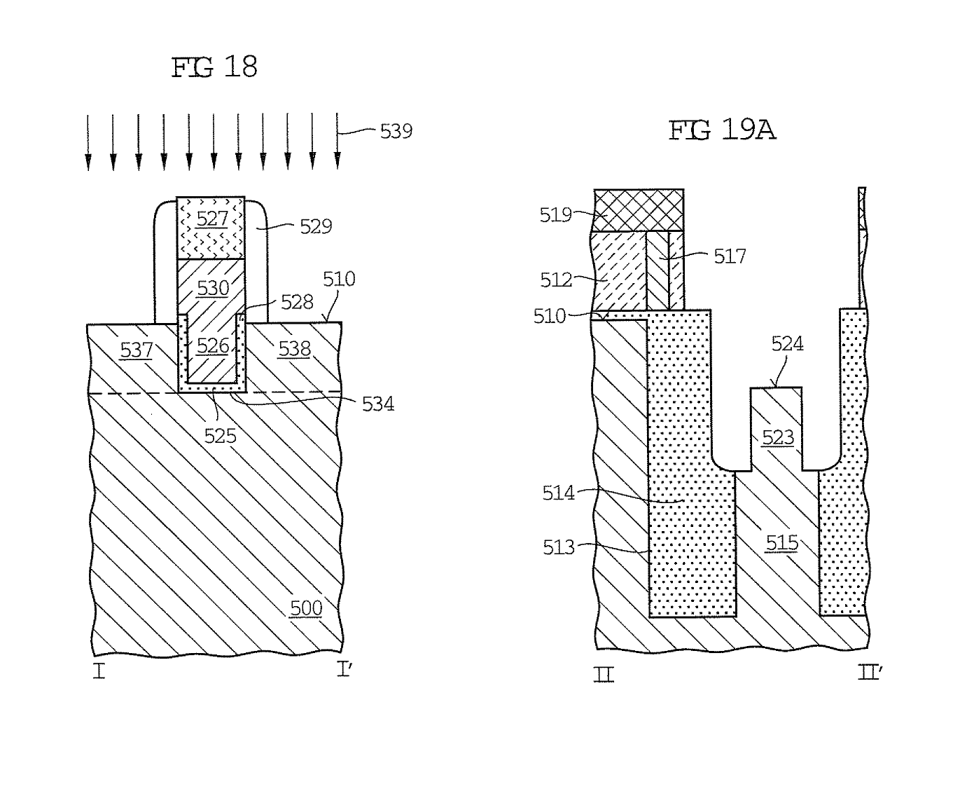

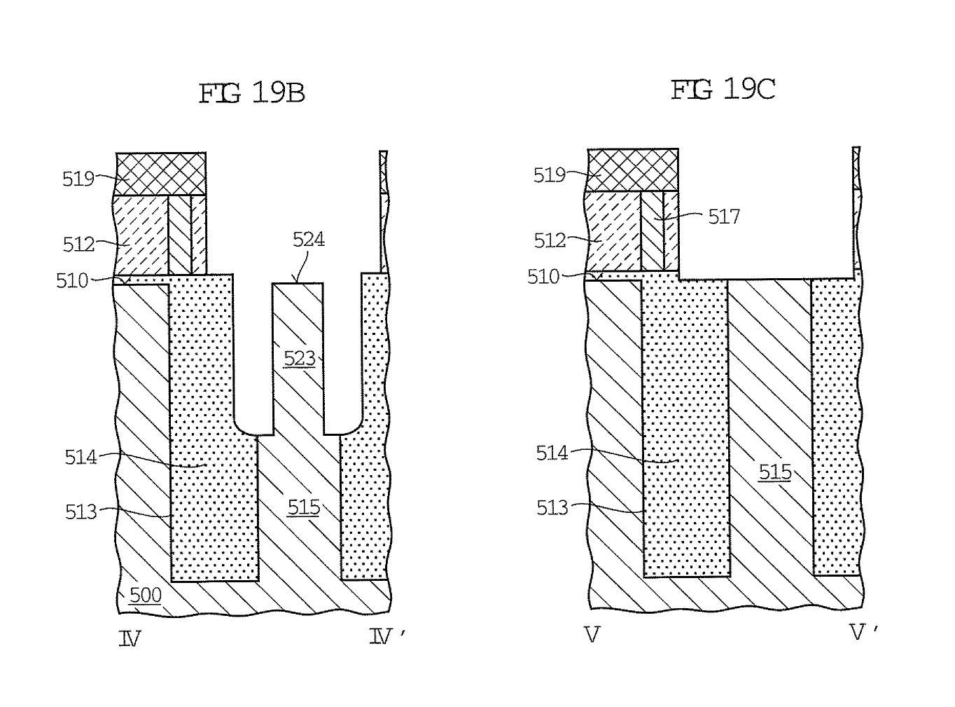

FIG. 13 illustrates several views of the resulting structure. As can be seen from FIG. 13A, in a direction parallel to the direction of the active area lines 515, the structure is maintained. As can be seen from FIG. 13B, pockets 521 are formed, the pockets 521 being adjacent to the active area 515. The plan view of the resulting structure is illustrated in FIG. 13C. Thereafter, optionally, an ion implantation process may be performed so as to provide a doped portion which prevents a punch-through between adjacent source/drain portions from occurring. Thereafter, optionally, an isotropic etching process for etching silicon material may be performed. As a consequence, the active area 515 may be locally thinned so as to form the narrowed fin-like portion 523. The resulting structure is illustrated in FIG. 14. As can be seen, the fin portion 523 is narrowed with respect to the width of the active area 515. The width of the pockets 521 is enlarged.

Up to now, all of the substrate portions may have been processed in the same manner. For example, the portions in which the transistors of the first, second and third types are to be formed may have been substantially identically processed. In the next process, the substrate portions in which the transistor of the first type is to be processed will be processed in a different manner than the substrate portions in which the transistor of the second type is to be formed. Accordingly, a further resist material is applied or covering the portion in which the transistor of the second type is to be formed while leaving the portion in which the transistor of the first type is to be formed uncovered. By way of example, if a memory device is to be formed, the support area may be covered with a resist material leaving the array portion uncovered. Then, etching processes are performed so as to remove the silicon nitride layer 512 as well as the silicon oxide layer 511 from the uncovered portions. Thereafter, the remaining portions of the hardmask layer 519 are removed.

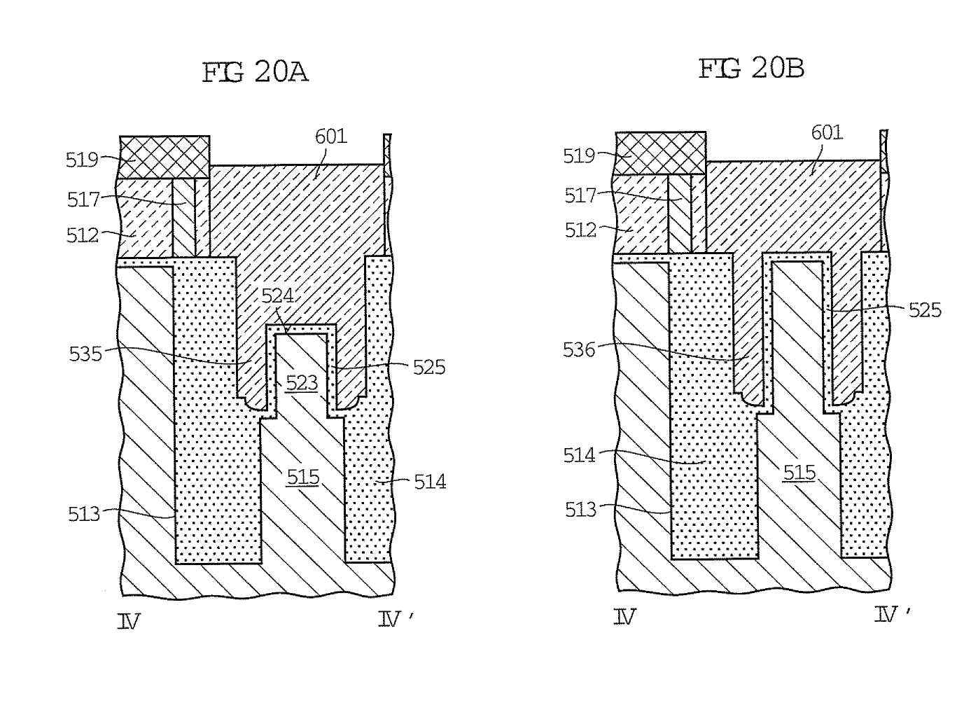

FIG. 15 illustrates various views of the substrate after this processing step. In particular, FIGS. 15A to 15C illustrate a substrate portion in which the transistor of the first type is to be formed, whereas FIGS. 15D to 15F illustrate views of the substrate in which the transistor of the second type is to be formed. As can be seen from FIG. 15A, a portion of the substrate surface 510 is exposed. As can further be seen from FIG. 15B, the top surface 524 of the narrowed fin-like portion 523 now is uncovered. FIG. 15C illustrates a plan view of the resulting substrate portion.

As can be seen from FIG. 15D, which is taken between III and III′, the complete active area line 515 is covered with the silicon oxide layer 511 as well as the silicon nitride layer 512. As can be seen from the cross-sectional view which is taken perpendicularly with respect to the view illustrated in FIG. 15D between IV and IV′, the fin-like portion 523 is covered with a silicon oxide layer 511 as well as the silicon nitride layer 512. FIG. 15F illustrates a plan view of the resulting substrate portion.

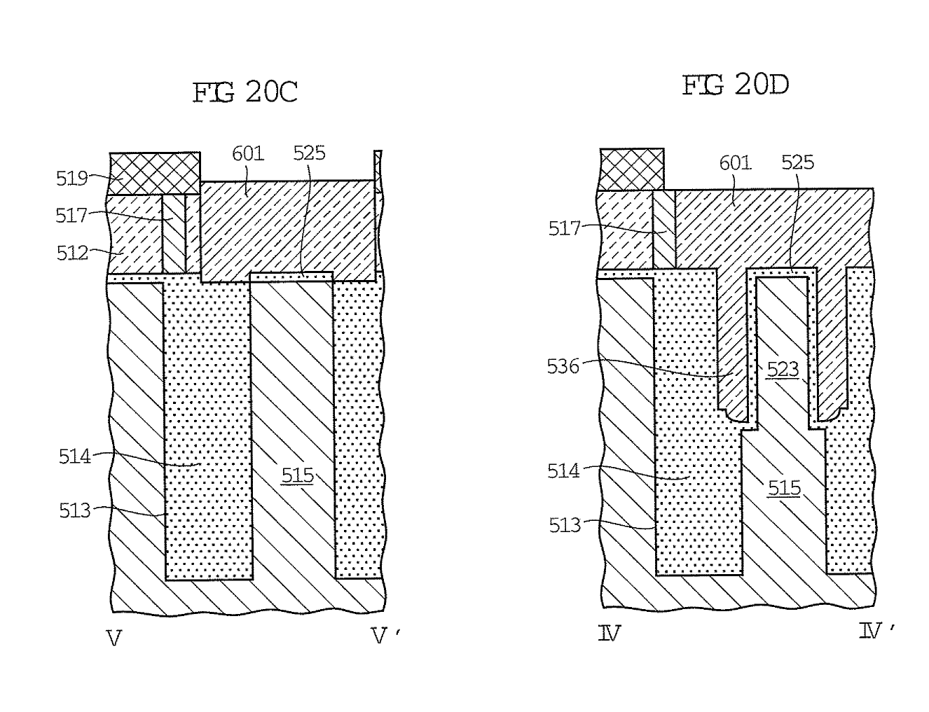

Thereafter, an etching process is performed so as to etch silicon material. For example, this may be accomplished by an anisotropic silicon etching process which may, optionally, be followed by an isotropic silicon etching process. The resulting structure is illustrated in FIG. 16. As can be seen from FIG. 16A, now, a gate groove 534 is formed in the substrate surface 510. As can be seen from FIG. 16B, the top surface 524 of the fin-like portion 523 now is recessed. If the spacers of the sacrificial material 517 were made of polysilicon, also these polysilicon spacers will be removed. FIG. 16C illustrates a plan view of the resulting structure. Due to the isotropic etching process, the corners of the channel to be formed may be further rounded.

Thereafter, the remaining portions of the further resist material are removed. Then, the remaining portions of the silicon nitride layer 512, 518 may be removed. Optionally, an annealing process may be performed in hydrogen. For example, this annealing process may be performed at a temperature of approximately 800° C. for typically one minute. As a result, the upper edges of the fin-like portion 523 may be shaped so as to have a round or circular form. For example, as a result of minimizing the surface energy, during this annealing process, the silicon material is rounded so as to obtain fin-like portions 523 having a rounded or a circular cross-section. A cross-sectional view of the substrate after performing such an annealing process is illustrated in FIG. 16D. Thereafter, the gate dielectric 525 may be formed in a manner as is conventional. In addition, on the sidewall portions of the gate groove 534, sidewall spacers 534 made of silicon oxide or another dielectric material may be formed. For example, an ion implantation process with nitrogen ions may be performed so as to dope the fin-like portion 523. Due to this doping, the oxide growth on the horizontal silicon portions will be retarded. Thereafter, a gate oxide will be grown so as to result in a larger thickness on the sidewall portions than on the bottom portion of the gate groove 534. As a further modification, a double process oxidation may be performed. During a first oxidation process, the inner spacer is formed, followed by an anisotropic etching process to remove the oxide in the bottom portion. Thereafter, a second oxidation process may be performed so as to form the gate oxide on the bottom portion of the gate groove 534. The methods described above may as well be combined with each other.

Thereafter, a conductive material 526 may be deposited, followed by, optionally, a suitable capping layer 527. By way of example, the material of the gate conductor may include many suitable conductive materials such as polysilicon, metal, for example, tungsten, TiN, metal silicides and others. Then, a patterning process will be performed so as to pattern the gate electrodes and the wordlines, respectively.

As a result, the structure illustrated in FIG. 17 may be obtained. As can be seen, single wordlines 531 are formed. For example, as is illustrated in FIG. 17A, a gate electrode 530 is formed, the gate electrode being disposed in a gate groove 534. As can be seen from FIG. 17B, a wordline extends perpendicularly with respect to the direction of the active areas 515, as can as well be seen from FIG. 17C.

As an alternative, the conductive material may also be recessed, followed by a deposition of insulating material. Thereby, a transistor includes a buried wordline which is, for example, illustrated in FIG. 5, may be obtained.

As can be seen from FIG. 17A, a spacer 534 may be laterally adjacent to the sidewalls of the gate groove 534. Accordingly, depending on the thickness of the spacer layer 528, the length of gate electrode 532 may be adjusted. For example, the length of the gate electrode may be smaller than the width of the gate groove 534. Accordingly, it is possible to form a gate electrode 532 having a sub-lithographic gate length, for example, a gate length which is smaller than the minimal structural feature size F.

In the substrate portion in which the transistor of the second type is to be formed, also wordlines are formed in the same manner as has been illustrated in FIGS. 17A to 17C. As can be seen from FIG. 17D, the bottom portion of the gate conductive layer 526 is disposed above the substrate main surface 510. The gate dielectric 525 is disposed above the substrate main surface 510. In addition, in a cross-sectional view which is perpendicular with respect to the cross-sectional view of FIG. 17D, a fin-like portion 523 of the active area 515 is formed. The fin-like portion 523 is enclosed at three sides thereof by a gate electrode 532. The top surface of the fin-like portion 524 is disposed at the same height as the substrate main surface 510. Since the transistor of the first type illustrated in FIGS. 17A, 17C and the transistor of the second type, illustrated in FIGS. 17D, 17E, have been manufactured by performing partially the same processes and since both transistors are formed in one single substrate, the vertical portions 535 of the transistor of the first type extend to the same depth d2 as the depth d1 of the vertical portions 536 of the transistor of the second type.

Due to the special processes which have been explained above, by which the position of the openings 521 is determined by the position of the hardmask portions 512 as is illustrated in FIG. 10A, the position of the vertical portions of the gate electrode is defined in a self-aligned manner. Accordingly, the correct adjustment of the position of the vertical portion does not depend on an overlay accuracy of a lithographic method. To be more specific, in the photolithographic method illustrated with respect to FIGS. 12A to 12C, an alignment error of the openings 520 does not necessarily result in a displacement of the vertical portions of the gate electrode.

A transistor of the third type may as well be formed by performing the processes which have been described with reference to FIG. 17. To this end, a suitable gate dielectric 525, the gate conductor 526 as well as the capping layer 527 are deposited on a substrate portion in which no pockets are defined. Thereafter, the gate stack is patterned in the manner which has been described with reference to the transistor of the first and the second types, respectively. As a result, a gate electrode which is similar to the one illustrated in FIG. 17D is obtained. Thereafter, sidewall spacers 529 may be formed adjacent to the gate electrodes 532, 530. For example, the spacers 529 may be made of silicon oxide and/or silicon nitride. Thereafter, the usual source/drain implantation processes 539 may be performed so as to provide the first and second source/drain portions.

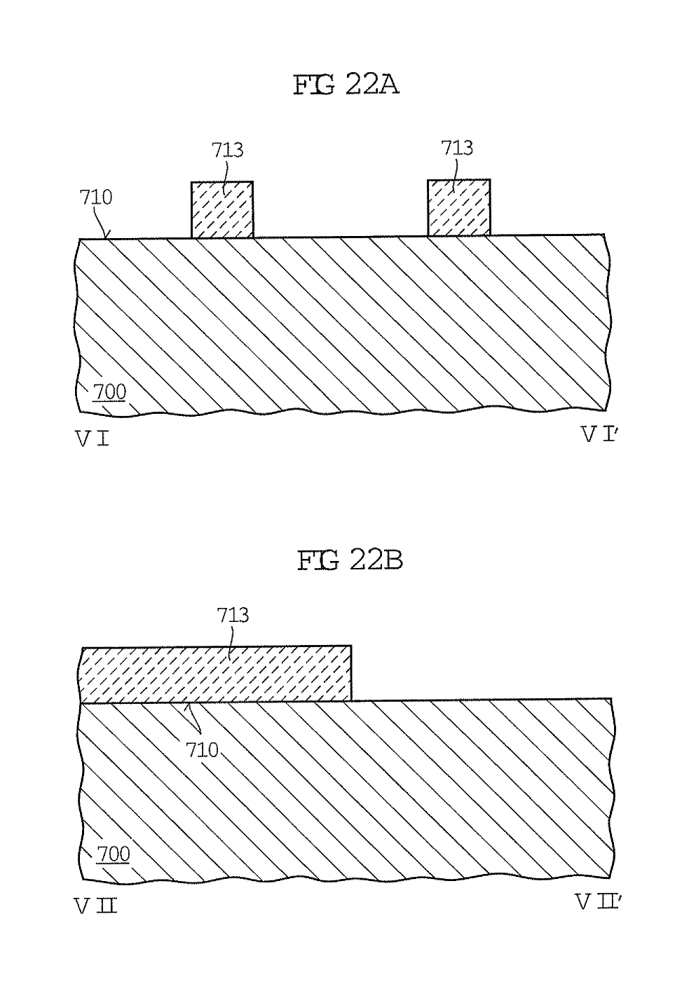

The resulting structure is illustrated in FIG. 18. As can be seen from FIG. 18, the first and second source/drain portions 537, 538 are provided adjacent to the gate groove 534.

According to another embodiment, the gate electrode may as well be formed by a damascene process. According to such a damascene process, first, an insulating material is deposited and the positions at which the gate electrode is to be formed are defined by removing the insulating material from these portions. Thereafter, a conductive material is deposited, followed by a planarizing process so as to fill the conductive material in the openings of the insulating layer. Thereafter, the remaining portions of the insulating layer are removed. As a result, conductive patterns are obtained.

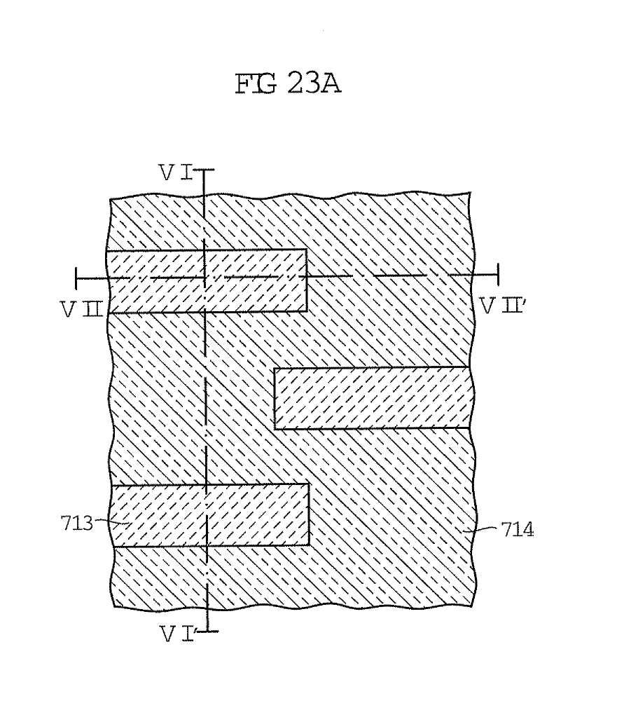

Starting point for performing the method according to this embodiment is the structure illustrated in FIG. 14. To be more specific, after performing the etching process which has been described with reference to FIG. 14, a resist material may be applied and patterned so as to cover the substrate portions in which the transistor of the second type is to be formed. Thereafter, the silicon nitride lines 512 and the silicon oxide layer 511 may be removed from the substrate portions in which the transistor of the first type is to be formed. Thereafter, a silicon etching process may be performed so as to recess the top surface 524 of the fin-like portion 523 as has been described above. Then, a silicon nitride etching process may be performed so as to remove the silicon nitride line from the exposed portion, followed by a silicon oxide etching process. The resulting structure is illustrated in FIG. 19. As can be seen from FIG. 19A, in a substrate portion in which the transistor of the first type is to be formed, the top surface 524 of the fin-like portion 523 is recessed. A portion of the insulating material 514 of the isolation trenches 513 is uncovered. In addition, FIG. 19B illustrates a substrate portion in which the transistor of the second type is to be formed. As can be seen, the top surface of the fin-like portion 523 is not recessed. Nevertheless, the top surface 524 of the fin-like portion is uncovered in FIG. 19B. A part of the insulating material 514 of the isolation trenches 513 is uncovered. FIG. 19C illustrates a substrate portion in which a transistor of the third type is to be formed. As can be seen, there is a planar surface of substrate material 515 and isolation trenches 513. In FIGS. 19A to 19C, the remaining portions of the hardmask 519 still are present on top of the silicon nitride layer 512.

Thereafter, a gate dielectric 525 is formed on the resulting surface of the active areas 515 as is common. Thereafter, a gate conductor 601 is deposited. For example, the gate conductor 601 may be any metal which is suitable for performing a damascene process. Then, a recess process is performed, for example, a CMP process or a recess etching process is performed so as to recess the upper surface of the gate conductor material 601. The resulting structure is illustrated in FIG. 20.

FIG. 20A illustrates a substrate portion in which the transistor of the first type is to be formed. As can be seen, the space between adjacent portions of the hardmask 519 is filled with a conductive material 601. In a similar manner, in FIGS. 20B and 20C, the gate conductor material 601 is provided in the space between adjacent portions of the hardmask layer 519. As can be seen from FIG. 20C a portion of the gate conductor material 601 is disposed on top of the active area 515. FIG. 20D illustrates a further modification in which the gate conductive material may be positioned in a self-aligned manner. According to this option, the position of the gate electrode 601 is determined in a self-aligned manner with respect to the position of the polysilicon spacer 517. Accordingly, the exact alignment of the hardmask opening 520 is not critical in order to obtain a gate electrode which is properly aligned with respect to the position of the active area 515.

The method of manufacturing several transistors of different types in one single substrate has been illustrated with respect to FIGS. 7 to 20. In particular, according to this embodiment, the gate electrode and, in particular, the position of the vertical portions of the gate electrode has been defined in a self-aligned manner with respect to the position of the active areas. According to another embodiment, the position of the gate electrode may as well be photolithographically defined.

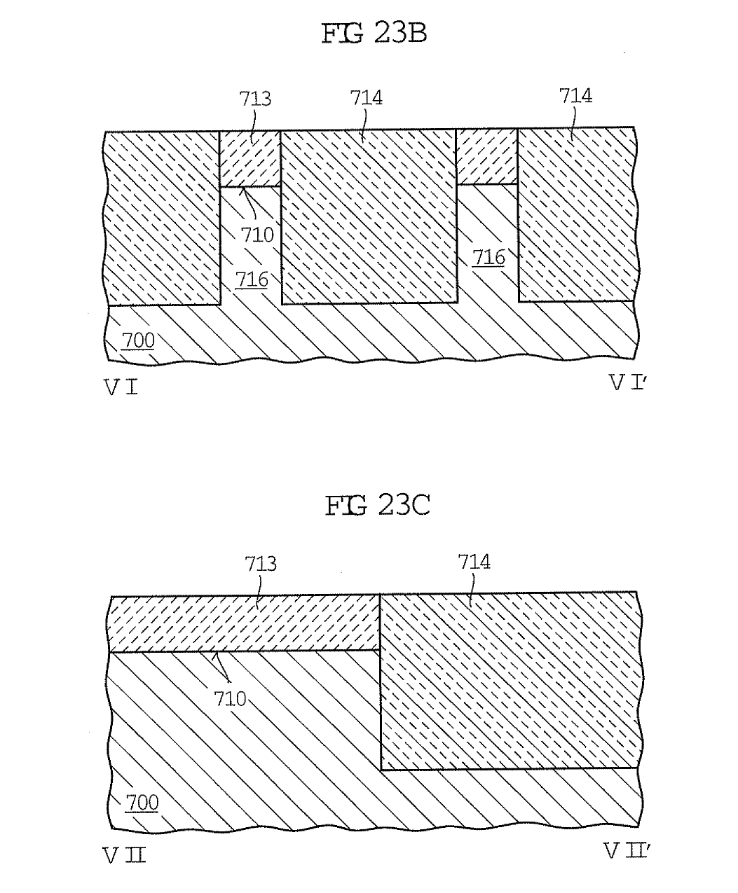

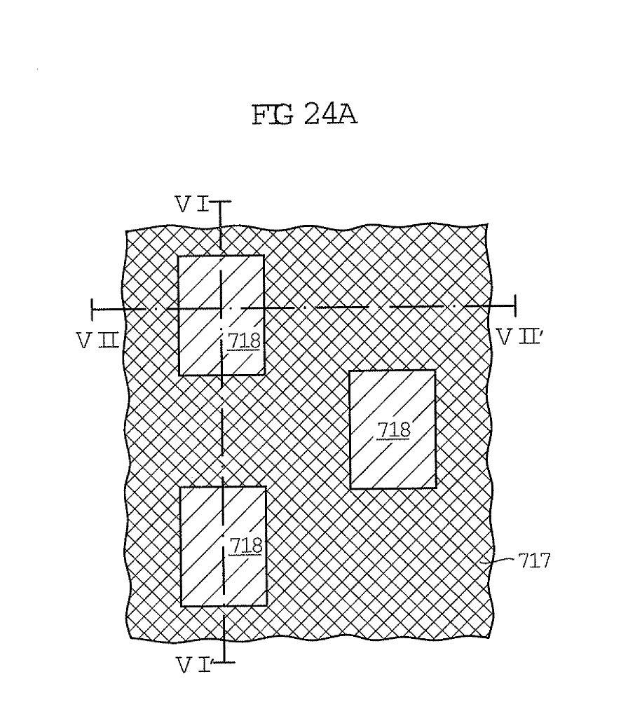

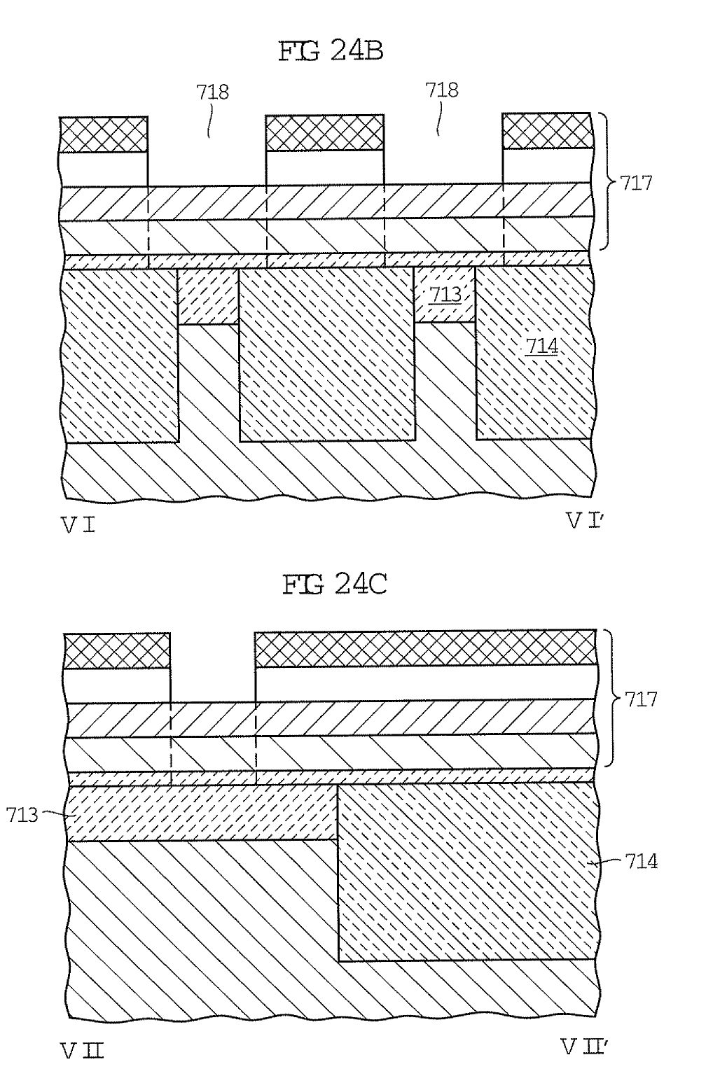

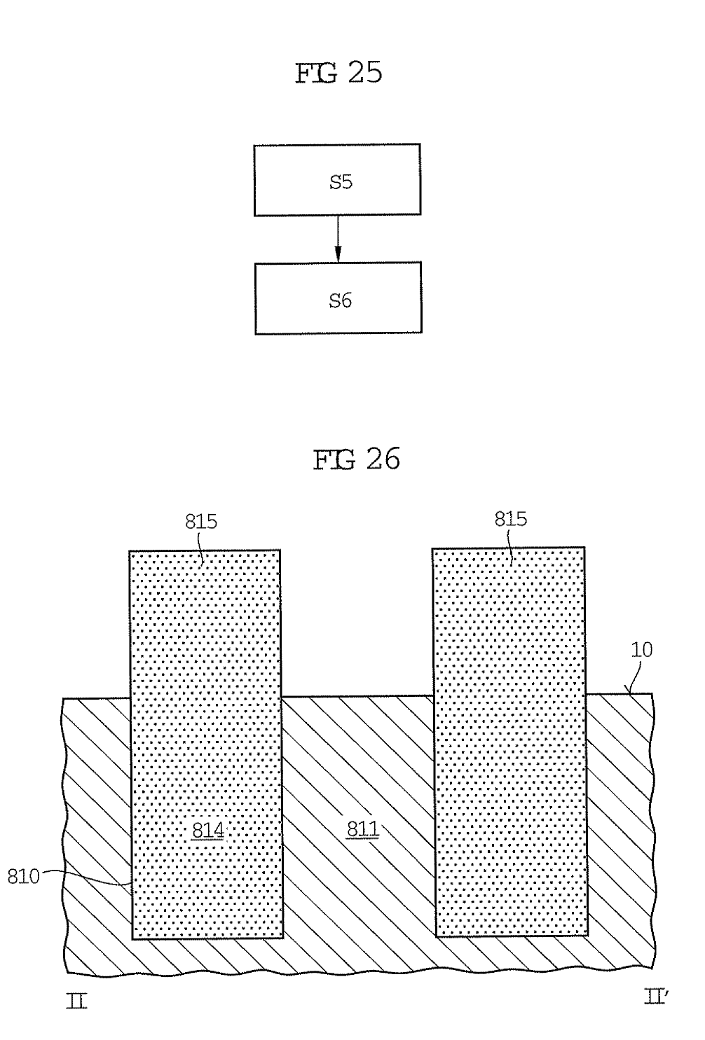

For example, active areas may be defined by depositing a suitable hardmask layer such as made of silicon nitride on the main surface 710 of a silicon substrate 700. In dependence of the layout of the transistor array to be formed, active areas are defined in the substrate material 700. In the present embodiment, the active areas may be formed as segmented active areas. Nevertheless, as has been mentioned above, they may as well be implemented as continuous active area lines. Accordingly, first, the hardmask layer is patterned in accordance with the layout of the active areas to be formed. For example, as a result, the structure illustrated in FIGS. 21 and 22 may be obtained. As can be seen from FIG. 21, the silicon nitride line segments 713 may be arranged in a checkerboard-like pattern. FIG. 22A illustrates a cross-sectional view which is taken between VI and VI′, whereas FIG. 23B illustrates a cross-sectional view between VII and VII′. Thereafter, taking the silicon nitride line segments 713 as an etching mask, an etching process is performed so as to define isolation trenches 714. The isolation trenches 714 may be filled with an insulating material such as silicon oxide. The resulting structure is illustrated in FIG. 23. In particular, FIG. 23A illustrates a plan view of the resulting structure, and FIGS. 23B and C illustrate cross-sectional views of the structure. As can be seen, isolation trenches 714 which are filled with an insulating material are disposed in the surface 710 of the substrate 700. Thereafter, several hardmask layers are deposited so as to form a hardmask layer stack 717. Then, the topmost layer of the hardmask layer stack 717 may be patterned using a suitable photoresist material and patterning the photoresist layer. For example, as is indicated in FIG. 24A, a mask having openings in the shape of dots which are arranged in a checkerboard-like pattern may be used. Nevertheless, depending on the layout of the array to be formed, any suitable other mask may be used. After correspondingly patterning the resist layer, the pattern is transferred into the topmost or any other layer lying below the hardmask layer stack 717. As can be seen from FIGS. 24B and 24C, hardmask openings 718 are formed. Taking the hardmask layer stack as an etching mask, further etching processes are performed. For example, first, the hardmask openings 718 may be extended so as to contact the top surface of the isolation trenches 714 as indicated by broken lines in FIG. 24. Then, a selective etching process is performed so as to etch silicon oxide selectively with respect to silicon nitride. As a consequence, pockets are formed in the isolation trenches 714 in a manner which is similar to the etching which has been explained above with respect to FIG. 13. Thereafter, taking the remaining portions of the hardmask layer stack 717 as a hardmask, the same processes as has been explained above may be used for providing the transistors of the first type, of the second type and, optionally, of the third type in one single substrate material.

As will be explained herein after, according to one embodiment, a FinFET or an integrated circuit having a FinFET may be manufactured by defining isolation trenches and by defining openings in a self-aligned manner with respect to the position of the isolation trenches in order to define vertical portions of a corresponding gate electrode.

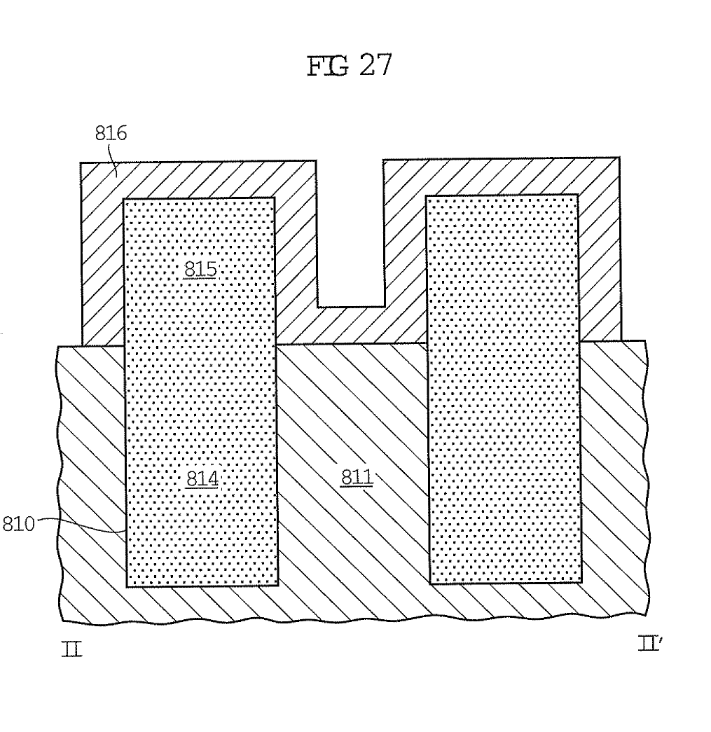

A flow-chart illustrating this method is illustrated in FIG. 25. As is illustrated, a method of manufacturing a FinFET having a gate electrode including vertical portions includes defining openings for defining the vertical portions. For example, first, isolation trenches that are adjacent to semiconductor substrate portions are defined (S5) and, thereafter, the openings may be defined in a self-aligned manner with respect to the position of the isolation trenches (S6). For example, forming the gate electrode may further include recessing the semiconductor substrate material. According to one embodiment, recessing the semiconductor substrate material may be performed only after defining the openings for defining the vertical portions. Accordingly, the FinFET may be manufactured by a simple process. For example, it is possible to determine at a very late processing step whether a specific FinFET is to be formed as a FinFET of the first or second type, respectively. For example, the isolation trenches may be defined by patterning a masking material so as to define masking material portions. Defining the openings includes providing spacers of the sacrificial material adjacent to patterned masking material portions. In this case, the openings may be etched in the insulating material in the isolation trenches. As an alternative, after defining the isolation trenches part of the material filling the isolation trenches may protrude from the isolation trenches. In this case, defining the openings may include providing spacers of a sacrificial material adjacent to the protruding material. Accordingly, when an etching process is to be performed, this etching will etch the substrate material. For example, the insulating material filled in the isolation trenches may not be etched during this etching process.

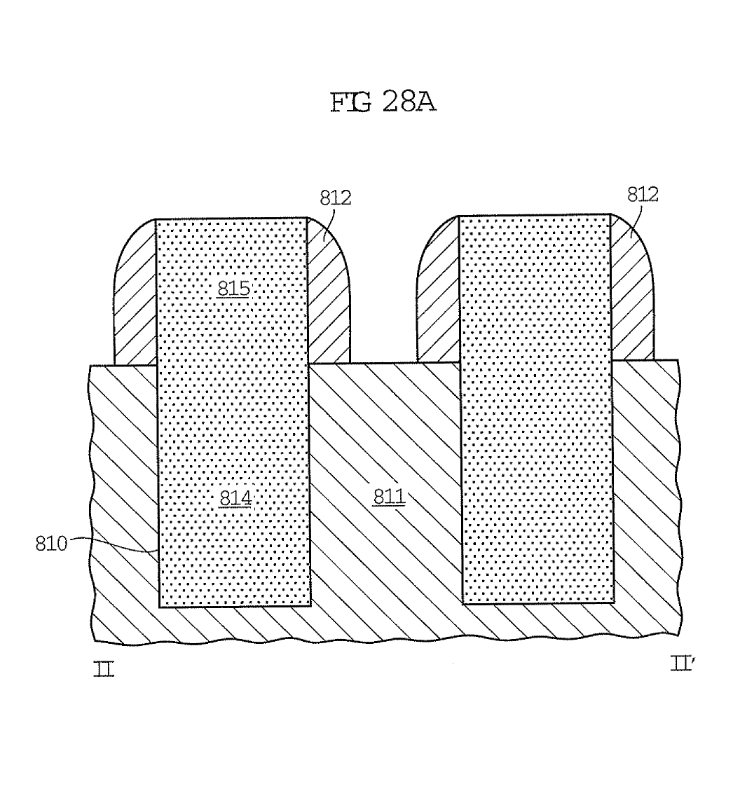

In the following, one exemplary process forming part of this embodiment will be explained in detail. Starting point for performing this embodiment may be the substrate which is illustrated in FIG. 7A to 7C, for example. To be more specific, isolation trenches 513 are formed in a semiconductor substrate 1 having a main surface 10. The isolation trenches 513 are filled with an insulating material 514. Between adjacent isolation trenches 513, active areas 515 are defined. Starting from the structure illustrated in FIG. 7, for example, the remaining portions of the silicon nitride layer 512 are removed by etching, for example. As a result, as is illustrated in FIG. 26 protruding portions 815 of the insulating material remain. In particular, the protruding portions 815 protrude from the substrate main surface 10. For example, the portions 815 may protrude by 100 to 500 nm.

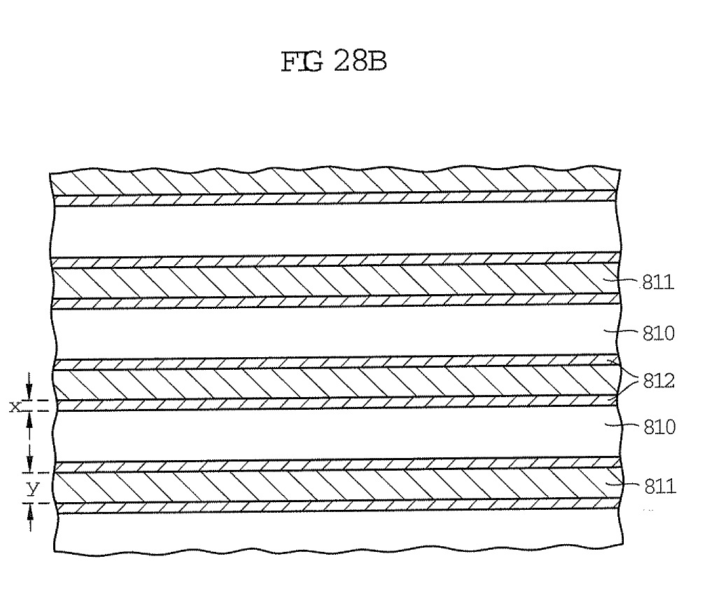

Thereafter, a liner layer 816 of a sacrificial material may be conformally deposited. For example, the sacrificial material may be polysilicon. For example, the liner layer 816 may have a thickness of approximately 5 to 50 nm. The resulting structure is illustrated in FIG. 27. Optionally, an anisotropic etching process may be performed so as to form spacers 812, which are adjacent to the sidewalls of the protruding portions 815.

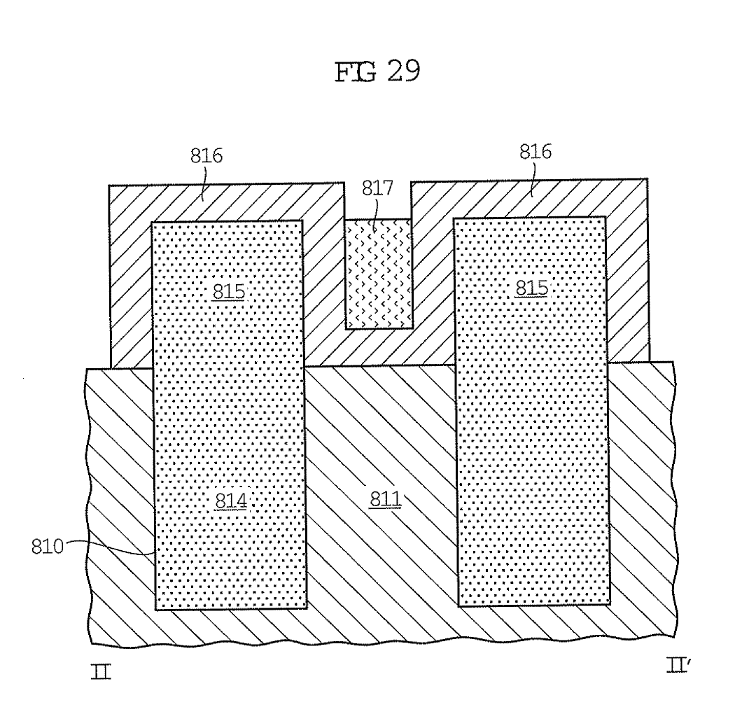

The resulting structure is illustrated in FIG. 28A. As can be seen, spacers are formed adjacent to the protruding portions 815, part of the substrate main surface 10 being exposed between adjacent spacers 812. FIG. 28B illustrates a plan view of an exemplary resulting structure. As can be seen, continuous isolation trenches 810 may be disposed in parallel with continuous active areas 811. Between the active areas and the isolation trenches, the spacers 812 are disposed. As can be seen, by varying the thickness x of the spacers 812, the width y of the exposed main surface portions of the active areas 811 may be adjusted.

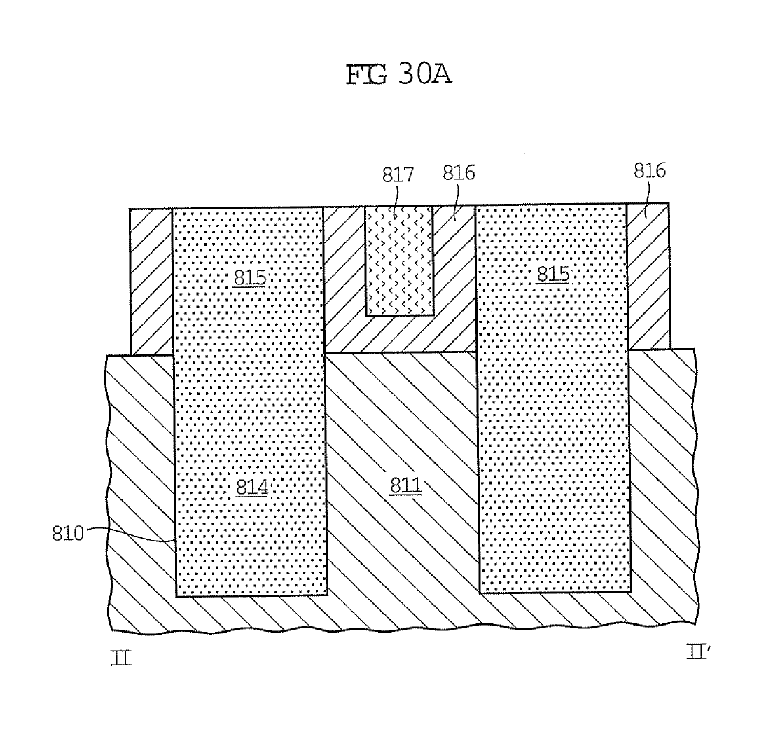

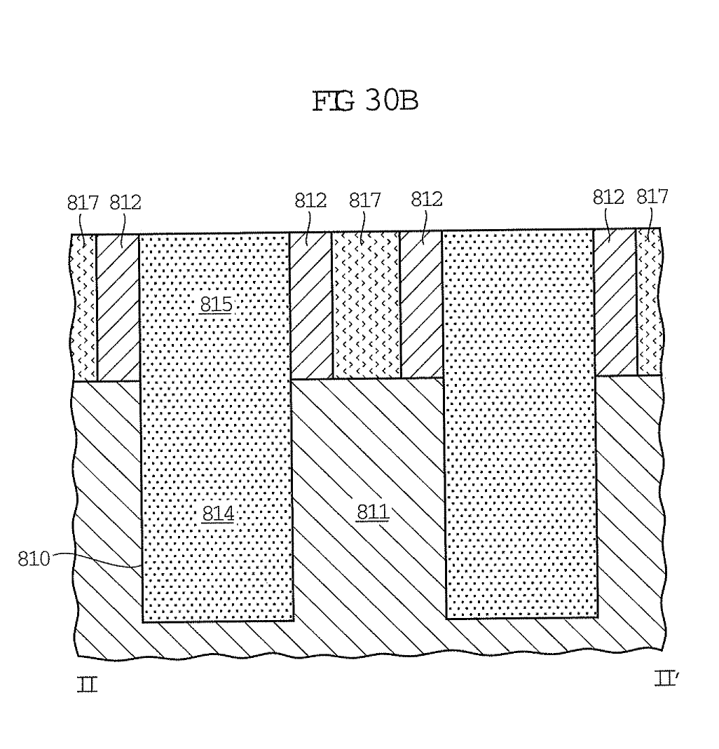

Thereafter, by way of example, a further cover material 817 may be deposited. By way of example, the cover material 817 may be silicon oxide. Nevertheless, any other material which may be etched selectively with respect to the material of the liner layer 816 may be taken. FIG. 29 illustrates an exemplary cross-sectional view in case the liner layer has not been etched by an anisotropic etching process. Thereafter, a planarization process or a recessing process may be performed. As a result, the upper surface of the protruding portions 815, of the liner layer 816 as well as of the cover layer 817 now is exposed. A resulting structure is illustrated in FIG. 30A for a case, in which the liner layer 816 has not been etched by an anisotropic etching process. FIG. 30B illustrates a cross-sectional view of the substrate in case the liner layer 816 has been etched so as to form spacers 812. As can be seen, now, part of the surface of the active area 811 is covered with the spacers 812. Another portion of the active area 811 is covered with the cover material 817.

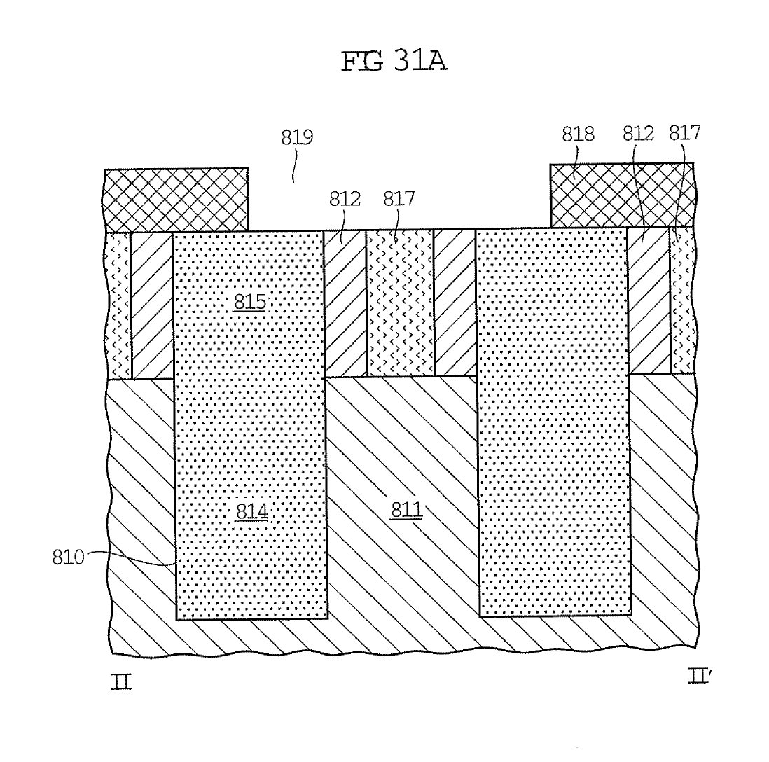

Thereafter, depending on the method of forming a memory device, for example, transistors in the support portion may be further processed. Further processes for processing the support portion may be performed. In addition, a suitable resist material may be applied and patterned so as to form a mask 818. For example, the mask 818 may include mask openings 819, leaving part of the spacers 812 uncovered. FIG. 31A illustrates a cross-sectional view of the resulting substrate. As can be seen, the mask opening is positioned in such a manner, that the central spacers 812 are uncovered.

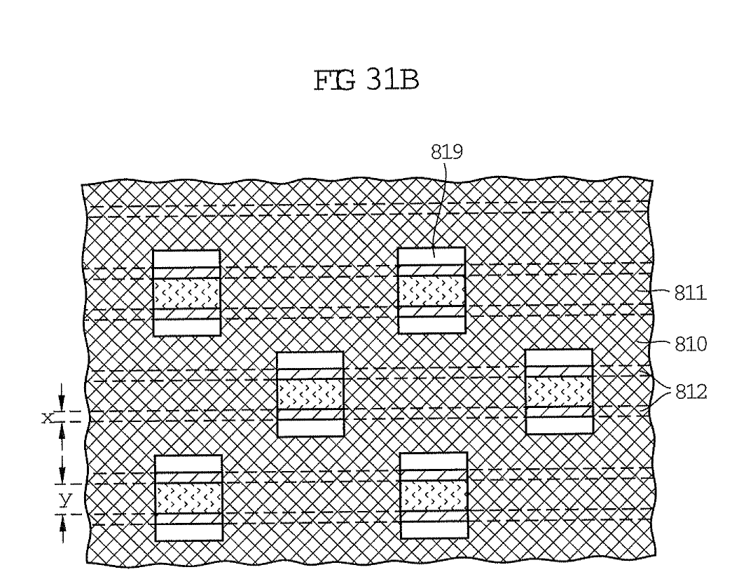

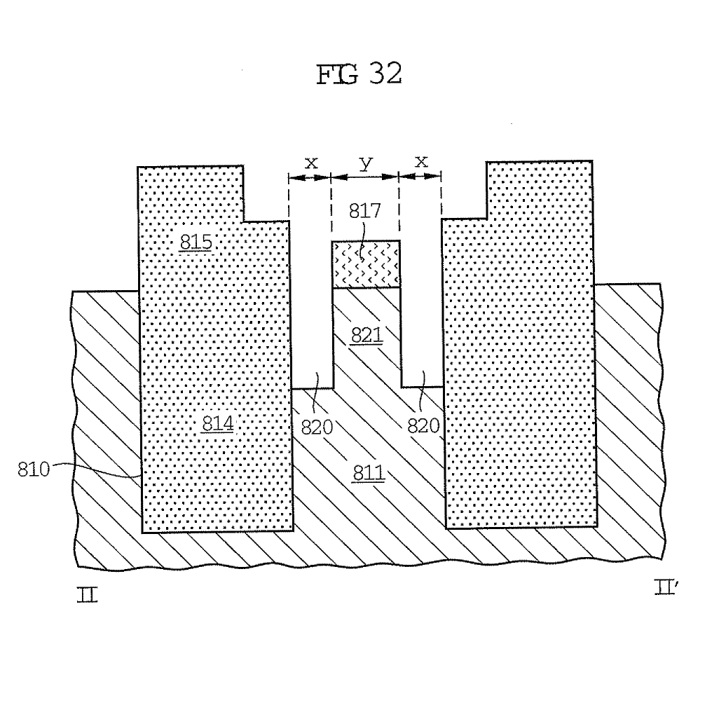

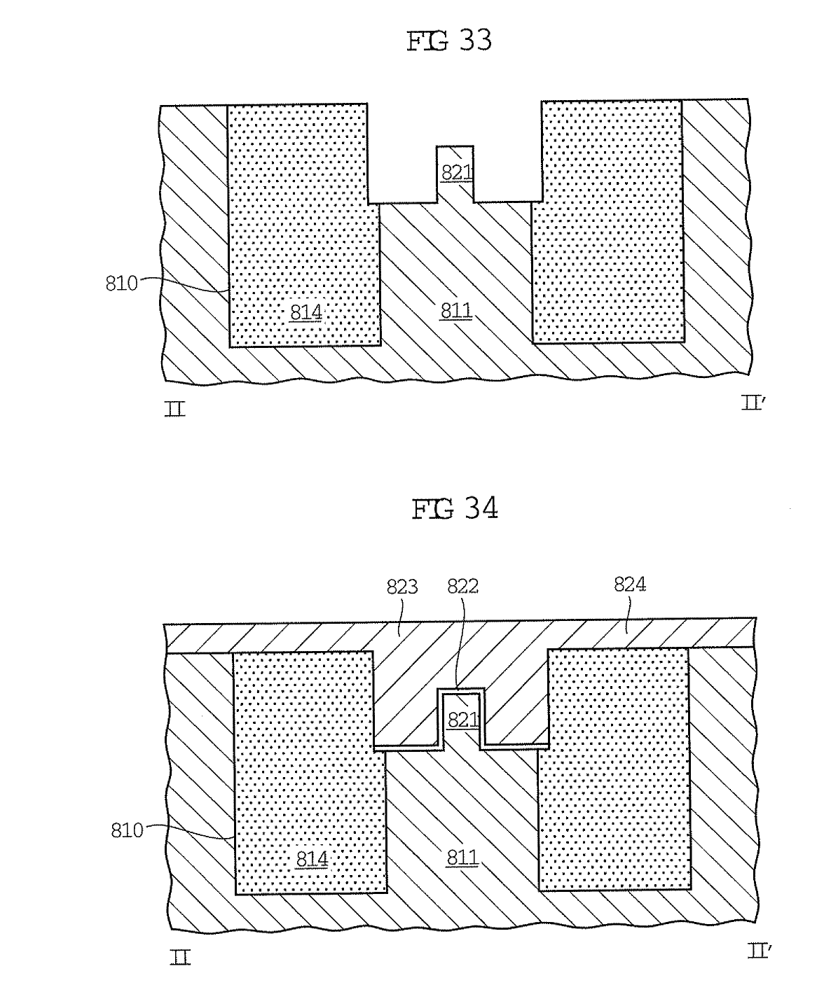

FIG. 31B illustrates a plan view of the resulting substrate. As can be seen, the openings 819 of the mask are positioned so as to open predetermined portions of the spacers 812. In the illustrated embodiment, the transistors may be arranged in a checkerboard arrangement. Nevertheless, the transistors may be arranged in any other arbitrary arrangement, for example, in the form of a regular or rectangular grid. Thereafter, the spacers 812 are etched selectively with respect to the insulating material 815 and 817. In this respect, a selective etching process refers to an etching process in which a first material (for example silicon nitride) is etched at a much higher etching rate than another material (for example silicon oxide). As a result, as can be seen from FIG. 32, part of the insulating material 815 is etched as well, 817. Pockets 820 are formed adjacent to the fin-like portion 821. As can be seen, the width of each of the pockets 820 and, thus, the remaining width of the fin-like portion 821 depends on the thickness of the liner layer 816, which has been deposited in the process explained with reference to FIG. 27. For example, the width of the pockets 820 may be approximately more than 5 nm and, for example, less than 25 nm. Thereafter, in the illustrated embodiment, the remaining portion of the insulating layer 817 is removed from the surface of the fin-like portion 821. By this etching process, also the protruding portions 815 of the insulating material may be removed. If transistors of several types are to be formed in one single substrate by performing common etching processes, during the removal of the remaining portion of the cover material 817, substrate portions may be covered with a suitable resist material. After removing the remaining portion of the cover material 817, an etching process may be performed so as to recess the upper portion of the fin-like portion, thus defining a gate groove which has been explained above. The resulting structure is illustrated in FIG. 33. As can be seen from FIG. 33, the top most surface of the fin-like portion 821 now is recessed. Due to this recessing process, also the width of the pockets 820 has been enlarged. Thereafter, as is common, a gate dielectric 822 may be formed or deposited, followed by a suitable gate electrode material 823. A word line 824 may be formed. As a result, as can be seen from FIG. 34 a transistor of the first type is formed, in which a major part of the vertical portions is disposed in the silicon substrate. For example, by adjusting the parameters of the etching processes described with reference to FIG. 33, the pockets 820 may not be extended so as to extend into the isolation trenches. In this case, the vertical portions of the transistors are not disposed in the isolation trenches 810.

As has been explained above, the openings for defining the vertical portions are defined in a self-aligned manner with respect to the position of the isolation trenches. For example, an insulating material 815 may protrude from the isolation trenches and spacers of a sacrificial material are provided adjacent to the protruding material. By selectively removing these spacers, the openings may be formed in a self-aligned manner. By adjusting the thickness of the spacers, the width of the active areas to be formed may be determined.

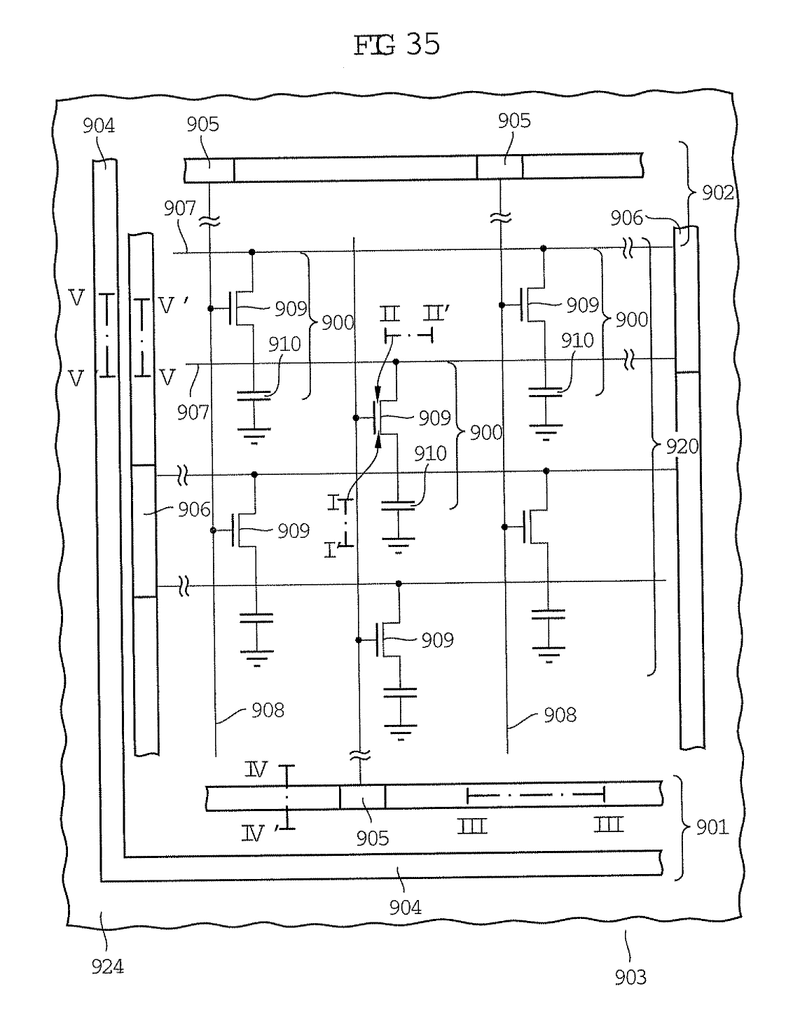

FIG. 35 illustrates a plan view of an integrated circuit 903, which may be implemented as a memory device 924. The memory device 924 may include the transistors, which have been described above. For example, the memory device illustrated in FIG. 35 includes an array portion 920, in which memory cells 900 are disposed, and a support portion 901. The support portion 901 may include a core circuitry 902 and the peripheral portion 904. For example, wordline drivers 905 may be disposed in the core circuitry 902. The core circuitry may include sense amplifiers 906 for sensing the received signals. As is common, the support portion 901 and the memory cell array 920 may be formed on one single semiconductor chip. Each of the memory cells 900 may include a storage element 910 and a transistor 909. Examples of the storage element 910 include storage capacitors and resistive storage elements and others which are generally well-known. The memory cell array may include wordlines 908, which are connected with the gate electrodes of the corresponding transistors 909. The wordlines 908 may be driven by wordline drivers 905. A doped portion of the transistors 909 may be connected with corresponding bitlines 907, the bitlines 907 being connected with sense amplifiers 906. For example, the access transistors of the individual memory cells 900 may be implemented as the transistor of the first type which has been described herein above. The transistors present in the support portion 901 may be implemented as transistors of the second type and, optionally, as transistors of the third type. For example, the cross-sectional view between III and III′ as well as between IV and IV′ may be taken in the support portion 901, as is illustrated in FIG. 35, for example. The cross-sectional view between V and V′ may be taken in the support portion 901, for example in the core circuitry 902 or in the peripheral portion 904. The cross-sectional views between I and I′ as well as between II and II′ may be taken in the memory cell array portion 920.

Nevertheless, as is clearly to be understood, the transistor of the first type may as well be present in the support portion 901. The transistors of the second and, optionally, of the third type may as well be present in the array portion 920. Accordingly, any of the cross-sectional views between III and III′ as well as between IV and IV′ may be taken in the array portion 920. The cross-sectional view between V and V′ may be taken in the array portion 920. The cross-sectional views between I and I′ as well as between II and II′ may as well be taken in the support portion 901.

The illustrated equivalent circuit diagram of FIG. 35 is only by way of example. As is clearly to be understood any other layout may be taken for implementing a memory device or an integrated circuit according to embodiments of the invention. For example, the memory cell array may be arranged in any arbitrary configuration, having the folded-bitline configuration, open-bitline configuration, twisted-bitline configuration and others. Any of the conductive lines 908, 907 may be arranged in an arbitrary orientation with respect to the orientation of the support portion 901.

The integrated circuit as disclosed within this specification may be implemented in any kind of digital circuits or analogous circuits, having, for example, current mirrors or comparators. The integrated circuit is, for example, useful in any applications where different thresholds, different channel lengths of the transistors or other varying characteristics may be useful.

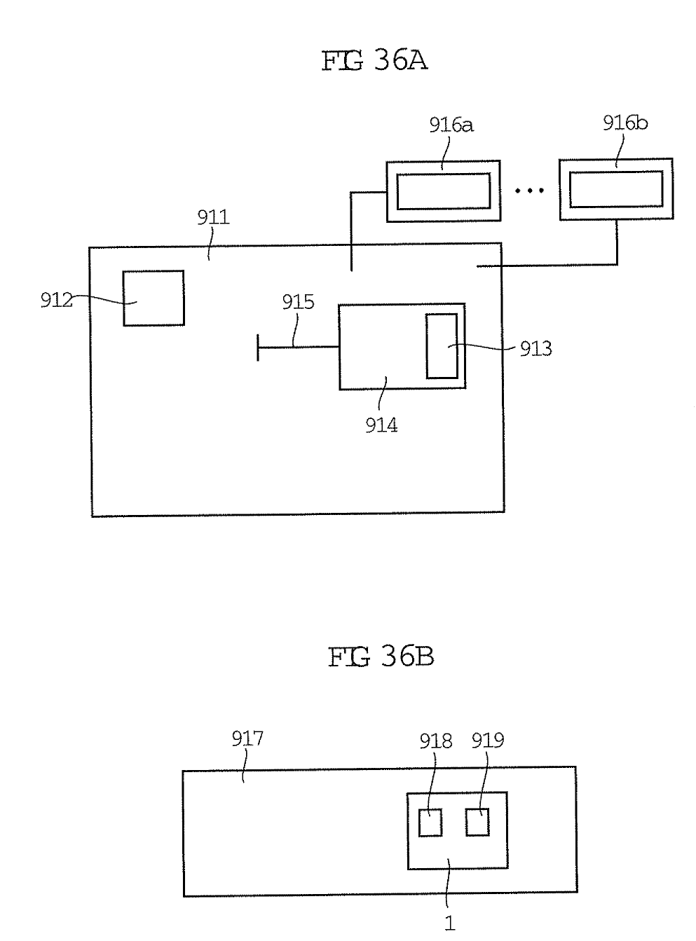

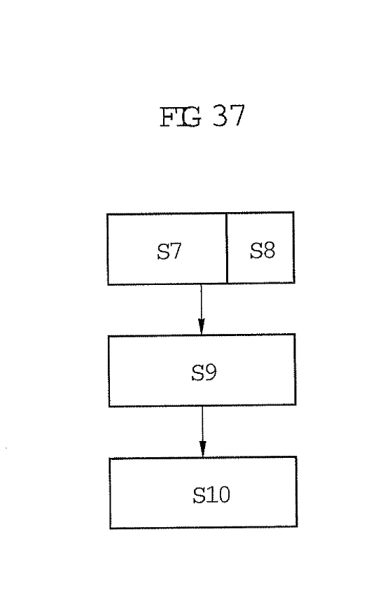

FIG. 36A schematically illustrates an electronic device 911 according to one embodiment. As is illustrated in FIG. 36A, the electronic device 911 may include an interface 915 and a component 914 which is adapted to be interfaced by the interface 915. The electronic device 911, for example and the component 914 may include an integrated circuit 913 or a semiconductor chip as has been explained above. The component 914 may be connected in an arbitrary manner with the interface 915. For example, the component 915 may be externally placed so as to be connected with the interface 915. The component 915 may be housed inside the electronic device 911 and may be connected with the interface 915. By way of example, it is also possible that the component 915 is removably placed into a slot which is connected with the interface 915. When the component 914 is inserted into the slot, a semiconductor chip or integrated circuit 913 is interfaced by the interface 915. The electronic device 911 may further include a processing device 912 for processing data. In addition, the electronic device 911 may further include one or more display devices 916a, 916b for displaying data. The electronic device may further include components which are configured to implement a specific electronic system. Examples of the electronic system include a computer, for example, a personal computer, or a notebook, a server, a router, a game console, for example, a video game console, as a further example, a portable video game console, a graphics card, a personal digital assistant, a digital camera, a cell phone, an audio system such as any kind of music player or a video system. For example, the electronic device 911 may be a portable electronic device.

FIG. 36B illustrates a data processing system 917 having a semiconductor substrate 1 in which a transistor 918 of a first type and a transistor 919 of the second type as has been explained above are integrated. By way of example, the data processing system may be digital signal processing chip.

FIG. 37 illustrates by way of example a further embodiment of the present invention. According to this embodiment, a method of manufacturing an integrated circuit includes forming a FinFET (S7) and providing a planar transistor (S8). The FinFET includes a gate electrode including vertical portions. According to the embodiment, the method includes providing isolation trenches in a semiconductor substrate (S9) to define substrate portions and defining openings (S10) in the planar surface of a least one region selected from the group consisting of the substrate portions and the isolation trenches for defining the vertical portions. In other words, the openings for defining the vertical portions are defined in the planar surface of the workpiece, wherein the workpiece includes substrate portions and isolation trenches. The vertical portions are defined by defining openings in this planar surface of the workpiece. To be more specific, the openings for defining the vertical portions are defined in the substrate surface or in the isolation trenches before defining, for example, a gate groove. Accordingly, the vertical portions may be defined independently from defining a gate groove.

According to one embodiment, the gate electrode of the FinFET as well as the gate electrode of the planar transistor may be made from the same layers. Accordingly, the FinFET as well as the planar transistor may be processed by common processes. The method may further include recessing the substrate material, for example, for defining a gate groove. The recess of the substrate material is performed after defining the openings.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. An integrated circuit, comprising:
a FinFET of a first type comprising a first gate electrode and a FinFET of a second type comprising a second gate electrode wherein the first gate electrode is formed in a gate groove that is defined in a semiconductor substrate; and
wherein a bottom side of a portion of the second gate electrode is disposed above a main surface of the semiconductor substrate.

2. The integrated circuit of claim 1, comprising a planar transistor comprising a third gate electrode formed above the semiconductor substrate.

3. The integrated circuit of claim 1, comprising where portions of first or second gate electrodes are disposed in isolation trenches that are adjacent to semiconductor substrate portions.

4. The integrated circuit of claim 1, comprising where a bottom surface of the gate groove is disposed below the main surface of the semiconductor substrate.

5. The integrated circuit of claim 1, where the first gate electrode comprises first vertical portions and the second gate electrodes comprises second vertical portions, the first and the second vertical portions extending to the same depth.

6. The integrated circuit of claim 1, comprising where an upper surface of the first gate electrode is disposed beneath the main surface of the semiconductor substrate.

7. The integrated circuit of claim 1, wherein the FinFET of the first type and the FinFET of the second type each comprise channels having the same width.

8. The integrated circuit of claim 1, comprising where a channel width of any of the FinFET of the first type and the FinFET of the second type is smaller than a width of a source/drain portion of the FinFET.

9. The integrated circuit of claim 1, comprising wrap-around contacts which are adjacent to a source/drain portion of the FinFET.

10. A memory device comprising:
a plurality of memory cells, each of the memory cells including a storage element and an access transistor, wherein the access transistors include FinFETs of a first type comprising a first gate electrode being formed in a gate groove that is defined in a semiconductor substrate; and
FinFETs of a second type comprising a second gate electrode wherein a bottom side of a portion of the second gate electrode is disposed above a main surface of the semiconductor substrate.

11. The memory device of claim 10, where the first gate electrode comprises first vertical portions and the second gate electrodes comprises second vertical portions, the first and the second vertical portions extending to the same depth.

12. The memory device of claim 10, comprising where an upper surface of the first gate electrode is disposed beneath the main surface of the semiconductor substrate.

13. A memory device comprising:
an array portion including a plurality of memory cells being at least partially formed in a semiconductor substrate;
a support portion including FinFETs of a second type comprising a second gate electrode wherein a bottom side of a portion of the second gate electrode is disposed above a main surface of the semiconductor substrate; and
the memory device further comprising FinFETs of a first type comprising a first gate electrode being formed in a gate groove that is defined in a semiconductor substrate.

14. An integrated circuit, comprising:
a FinFET of a first type comprising a first gate electrode and a FinFET of a second type comprising a second gate electrode;
wherein the first gate electrode is formed in a gate groove defined in a semiconductor substrate; and
a current path between a first and a second contact regions of the FinFET of the second type comprises only horizontal components.

15. The integrated circuit of claim 14, comprising where a bottom surface of the gate groove is disposed below a main surface of the semiconductor substrate.

16. The integrated circuit of claim 14, where the first gate electrode comprises first vertical portions and the second gate electrodes comprises second vertical portions, the first and the second vertical portions extending to the same depth.

17. The integrated circuit of claim 14, comprising a planar transistor comprising a third gate electrode which is formed above the semiconductor substrate.

18. A FinFET comprising:
a gate electrode including vertical portions, the FinFET being formed in a semiconductor substrate portion, isolation trenches being adjacent to the semiconductor substrate portion; and
wherein the vertical portions are self-aligned with respect to the position of the isolation trenches.

19. The FinFET of claim 18, comprising wherein the vertical portions are disposed in the semiconductor substrate.

20. The FinFET of claim 18, comprising wherein the vertical portions are disposed in the isolation trenches.

21. The FinFET of claim 18, comprising wherein a wrap-around contact adjacent to a source/drain portion of the FinFET.

22. An integrated circuit including a FinFET comprising:
a gate electrode including vertical portions, the FinFET being formed in a semiconductor substrate portion, isolation trenches being adjacent to the semiconductor substrate portion; and
wherein the vertical portions are self-aligned with respect to the position of the isolation trenches.

23. The integrated circuit of claim 22, comprising wherein the vertical portions are disposed in the semiconductor substrate.

24. The integrated circuit of claim 22, comprising wherein the vertical portions are disposed in the isolation trenches.

25. A method of manufacturing an integrated circuit, comprising:
forming a FinFET of a first type comprising a first gate electrode and forming a FinFET of a second type comprising a second gate electrode; wherein
forming the first gate electrode comprises defining a gate groove in a semiconductor substrate and filling the gate groove with part of the first gate electrode; and wherein
forming the second gate electrode is configured so that a bottom side of a portion of the second gate electrode is disposed above a main surface of the semiconductor substrate.

26. The method of claim 25, wherein forming the first and the second gate electrodes comprises defining first and second openings for forming first and second vertical portions of the first and second gate electrodes, respectively.

27. The method of claim 26, comprising defining the first and second openings is accomplished before defining the gate groove.

28. The method of claim 26, comprising defining the first and second openings by common etching processes.

29. The method of claim 26, comprising defining the first and second openings by etching the semiconductor substrate.

30. The method of claim 26, comprising defining the first and second openings by etching insulating material that is disposed in isolation trenches that are adjacent to the semiconductor substrate.

31. The method of claim 26, comprising defining isolation trenches that are adjacent to the semiconductor substrate, wherein the first and second openings are defined in a self-aligned manner with respect to the position of the isolation trenches.

32. The method of claim 31, comprising defining the isolation trenches comprises patterning a masking material and wherein defining the first and second openings comprises providing spacers of a sacrificial material adjacent to patterned masking material portions.

33. The method of claim 31, comprising wherein after defining the isolation trenches part of a material filling the isolation trenches protrudes from the isolation trenches, wherein defining the first and second openings comprises providing spacers of a sacrificial material adjacent to the protruding material.

34. The method of claim 25, comprising forming the first and the second gate electrode comprises:
providing a sacrificial material over the semiconductor substrate;
defining openings corresponding to portions of the first and second gate electrodes respectively; and
filling a conductive material into the openings.

35. A method of manufacturing a FinFET comprising:
providing a gate electrode including vertical portions;
defining openings for defining the vertical portions; and
defining isolation trenches that are adjacent to semiconductor substrate portions, wherein the openings are defined in a self-aligned manner with respect to the position of the isolation trenches.

36. The method of claim 35, comprising defining the openings in the semiconductor substrate portions.

37. The method of claim 35, comprising defining the openings in the isolation trenches.

38. The method of claim 35, comprising defining a gate groove in the semiconductor substrate.

39. The method of claim 38, comprising defining the gate groove after defining the openings.

40. The method of claim 38, comprising defining the gate groove before defining the openings.

41. The method of claim 35, comprising defining the isolation trenches comprises patterning a masking material to define masking material portions and wherein defining the openings comprises providing spacers of a sacrificial material adjacent to patterned masking material portions.

42. The method of claim 35, comprising after defining the isolation trenches part of a material filling the isolation trenches protrudes from the isolation trenches, wherein defining the openings comprises providing spacers of a sacrificial material adjacent to the protruding material.

43. The method of claim 42, wherein providing the spacers comprises conformally depositing a layer of the sacrificial material, a thickness of the layer of the sacrificial material being selected in accordance with a thickness of an active area of the FinFET.

44. The method of claim 35, comprising recessing the semiconductor substrate material after defining the openings.

45. The method of claim 35, comprising providing wrap-around contacts in contact with a source/drain portion.

46. A method of manufacturing an integrated circuit, comprising:
forming a FinFET comprising a gate electrode including vertical portions and providing a planar transistor, the method of forming a FinFET comprising:
providing isolation trenches in a semiconductor substrate to define substrate portions; and
defining openings in the planar surface of at least one region selected from the group consisting of the substrate portions and the isolation trenches for defining the vertical portions.

47. The method of claim 46, comprising wherein the gate electrode of the FinFET as well as a gate electrode of the planar transistor are made from the same layers.

48. The method of claim 47, further comprising recessing the substrate material, being performed after defining the openings.
